(19) United States
(12) Patent Application Publication
(10) Pub. No.: US 2012/0212136 A1
(43) Pub. Date: Aug. 23, 2012

(54) PENETRATING PLASMA GENERATING APPARATUS FOR HIGH VACUUM CHAMBERS

(75) Inventor: Moshe Einav, Kfar Uriyah (IL)

(73) Assignee: MOSAIC CRYSTALS LTD., Herzliya (IL)

(21) Appl. No.: 13/392,810

(22) PCT Filed: Aug. 29, 2010
(86) PCT No.: PCT/IL10/00707

§ 371 Date: May 2, 2012

Related U.S. Application Data
(60) Provisional application No. 61/237,462, filed on Aug. 27, 2009.

(51) Int. Cl. H01J 37/32

(52) U.S. Cl. 315/111.41

(57) ABSTRACT

A plasma generating apparatus is provided with a high vacuum processing chamber and a transformer type plasmatron that is coupled with the high vacuum processing chamber. At least one gas source is coupled with the transformer type plasmatron, for introducing at least one gas into the transformer type plasmatron. The high vacuum processing chamber includes at least one entry port. The transformer type plasmatron includes: a radio frequency power source, for generating alternating current power; a plurality of conductors, coupled with the radio frequency power source; a closed loop discharge chamber, for confining the at least one gas; a plurality of high permeability magnetic cores, coupled around an outer portion of the closed loop discharge chamber and with the plurality of conductors; a plurality of apertures, located along an inner portion of the closed loop discharge chamber; and at least two dielectric gaskets.

### FIELD OF THE DISCLOSED TECHNIQUE

The disclosed technique relates to plasma generating apparatuses, in general, and to methods and systems for generating plasmas for uniform distribution on targets in high vacuum chambers, in particular.

### BACKGROUND OF THE DISCLOSED TECHNIQUE

Transformer-type plasmatrons refer to plasmatrons, or plasma generating apparatuses, for generating plasma using the physical principles employed in transformers. Transformer-type plasmatrons are known in the art. A transformer is an electrical device which transfers electrical energy (an alternating electric current (AC) and voltage pair) from a first circuit to a second circuit through inductively coupled conductors. The first circuit may be referred to as an input pair, with the second circuit being referred to as an output pair. In general, a transformer includes a core of high permeability magnetic material coiled on one side by an input conductor, known as the primary winding, and coiled on the other side by an output conductor, known as the secondary winding. Each conductor, i.e., the primary and the secondary windings, must form a closed path or a loop.

The mode of operation of a transformer is based on Faraday's law of induction. The input conductor is supplied by an alternating current, which induces an alternating magnetic field in the core of high permeability magnetic material, thereby magnetizing the core material. The magnetized core then induces an electric field in the output conductor. Apart from small losses of energy as heat in the core material, the input alternating current power to the input conductor is substantially equal to the output power of the output conductor. In general, the current and voltage of the output conductor are proportional to the number of windings in each of the primary winding and the secondary winding. For example, as the number of windings is increased in the primary winding, an increase in current and a decrease in voltage is thus produced in the secondary winding.

Plasma refers to a heated state of gas, sometimes known as the fourth state of matter, in which electrons can leave respective atoms and molecules, thus becoming free electrons moving in a macroscopic space. As a result, the atoms and molecules may be altered into ions, i.e., charged particles. In the case that the free electrons are positioned within an electric field, the free electrons can gain kinetic energy, hit other atoms and molecules and dislodge, or eject electrons from those atoms and molecules. A free electron can cause an electron in an atom or molecule to be ejected, thereby forming a new ion. A free electron can also knock a core orbital electron into an outer orbital, thereby forming an excited atom. A free electron can also break a chemical bond in a molecule, thereby forming two radicals (i.e., chemically active species). As such, those other atoms and molecules may then be altered into ions, radicals, ion-radicals and other charged particles. In addition, a free electron can recombine with an ion, thus co-annihilating. As plasmas comprise charged particles moving in an electric field, plasmas are electrical conductors. In the art of plasma generating apparatuses, the macroscopic space in which free electrons and ions (i.e., charge carriers) can move and travel is referred as a discharge chamber (herein abbreviated DCh). As plasmas may include free radicals, excited atoms and ionized particles, the various particles which make up a plasma can be referred to collectively as plasma constituents. Plasmas can be classified in a variety of manners. One such classification is based on the voltage of the electric field in which the plasma is maintained. Cold plasmas refer to plasmas which are maintained in low voltage electric fields, for example between approximately 0.1-10 volts/cm. Such cold plasmas can be produced by transformer-type plasmatrons, as detailed herein below. Usually, the pressure inside the DCh, where such cold plasmas are produced, ranges between 0.01-1000 pascal (herein abbreviated Pa), which is considered to be the low vacuum range. In general, in the high vacuum range (for example between 1×10⁻⁶-1×10⁻² Pa) and in the very low vacuum (i.e., high pressure) range (for example, above 1000 Pa), plasmas are maintained in high voltage electric fields. The electric field at which the plasma is maintained determines the partial fraction of the different constituents of the plasma and the plasma's density. Higher electric fields induce a high plasma density and a high ion to radical fraction while lower electric fields induce a low plasma density and a relatively low ion to radical fraction. In general, a DCh pressure can be determined for which the voltage of the electric field required for maintaining a plasma is minimal. At that pressure, the fraction of radicals to ions in the plasma will be maximal.

In a transformer-type plasmatron, high permeability magnetic cores are coiled on one side by conducting coils, thus forming the primary winding. The secondary winding of the transformer is a conducting gas which is contained in a closed tube which forms a single loop closed path winding. The closed or looped tube is the DCh and when alternating current is supplied via the primary winding to a plurality of high permeability magnetic cores coupled with the DCh and then ignited, the conducting gas in the DCh becomes a plasma. For the conducting gas to conduct and thus become a plasma, the DCh walls must be non-conductive, since otherwise, the induced voltage and current in the DCh will pass through the DCh walls. The DCh walls are made non-conductive by employing a dielectric material or by fragmenting the closed tube into a plurality of tubes coupled and interspaced by respective dielectric elements (such as dielectric gaskets). Furthermore, as the plasma heats up the DCh walls, the DCh walls must be heat-resistant or must be cooled. In transformer-type plasmatrons, radio frequency (herein abbreviated RF) alternating current power is supplied to the primary winding. The alternating current power supplied is typically in the low to medium RF range, for example between 50-1000 kilohertz (herein abbreviated kHz). Using good quality ferrite cores as the high permeability magnetic cores enable the use of medium RF, thus improving power usage efficiency of the transformer-type plasmatron and also reducing its physical size.

In transformer-type plasmatrons having a continuous supply of gas and an aperture in the closed tube, the plasma generated can be utilized to perform chemical reactions. The chemical reactions occur within the DCh or within a reactor which is an integral part of the DCh. Such a DCh may be constructed of quartz tubing or double-walled water-cooled metal chambers. Chemical reactions with plasma can also be performed in transformer-type plasmatrons by simply placing a substrate in the DCh and igniting the plasma. Such types of plasmatrons may have a widened section in the DCh loop where the substrate is placed to react with the plasma.

Looped tube transformer-type plasmatrons for chemical reactions are constructed of isolated tube sections that form a closed loop around a plurality of magnetic cores. The isolated tube sections can be made of aluminum or stainless steel. A portion of the DCh can be broadened and serve as a reactor or a processing chamber (herein abbreviated PCh). An inlet valve for the introduction of the conducting gas to the DCh and an outlet valve, such as a vacuum pump, for the disposal of gases from the DCh are placed on the perimeter of the DCh. In this manner, no difference in gas pressure is generated between the DCh and the reactor. A typical DCh may maintain a pressure in the range of 1-10 Pa, which is considered a low vacuum range. Such looped tube transformer-type plasmatrons are employed in the semiconductor industry for sputtering, plasma etching, reactive ion etching, plasma enhanced chemical vapor deposition and photochemical reactions. It is noted that high vacuum reaction environments (for example, molecular beam epitaxy, chemical beam epitaxy, atomic layer deposition and the like) do not usually gain an advantage from the variety of plasma constituents normally found in plasmas. Depositions which occur in such high vacuum reaction environments usually require very low energy reactants such as radicals, non-accelerated ions, low flux rates and low electric fields such that the DCh walls are not sputtered and do not contaminate the reactor.

Reactors used for such high vacuum reactions are typically on the scale of tens of centimeters, with the distance of an evaporation source to a target being on the order of a few hundred millimeters (herein abbreviated mm). A plasma source placed at such distance in such a reactor would be ineffective. Plasma constituents are very different in their masses, charges, energies and chemistries, thereby forming a non-uniform beam of particles which tend to recombine and annihilate. In practice, plasma constituents annihilate exponentially over distance. In addition plasmas can be described as being an unordered mix of different species, each having a specified lifetime, reactivity and thus utility. Changing the parameters which govern the generation of plasma can change the relative concentration of constituents and the amounts in the plasma, i.e., the plasma density. For example, higher maintenance voltages of the plasma may makes the plasma ion enriched, while lower maintenance voltages of the plasma may make the plasma enriched with free radicals.

Transformer-type plasmatrons are known in the art. U.S. Pat. No. 5,942,854 to Ryoji et al., entitled “Electron-beam excited plasma generator with side orifices in the discharge chamber” is directed to an electron-beam excited plasma generator which can effectively form samples of larger areas. The electron-beam excited plasma generator comprises a cathode, a discharge electrode, an intermediate electrode, a discharge chamber, a plasma processing chamber, a plurality of orifices and an accelerating electrode. The cathode emits thermions and the discharge electrode discharges a gas between the cathode and itself. The intermediate electrode is positioned coaxially with the discharge electrode in an axial direction. The discharge chamber fills with the discharged gas converted into a plasma by the cathode and the discharge electrode. The plasma processing chamber is formed adjacent to the discharge chamber with a partition wall disposed therebetween and is positioned so that a surface-to-be-processed of a workpiece-to-be-processed is positioned perpendicular to the axial direction of the intermediate electrode. The plurality of orifices allows electrons in the discharge gas plasma in the discharge chamber to enter into the plasma processing chamber. Each orifice is formed in the partition wall, each orifice being substantially perpendicular to the axial line of the intermediate electrode and distributed radially with respect to the axial direction of the intermediate electrode. The accelerating electrode is disposed in the plasma processing chamber and pulls out and accelerates electrons in the discharge chamber through the plurality of orifices.

U.S. Pat. No. 6,211,622 to Ryoji et al., entitled “Plasma processing equipment” is directed to plasma processing equipment for use with an electron-beam excited plasma generator. The equipment includes a plurality of extracting orifices, a discharge portion, a plasma processing chamber, a compartment and a plurality of accelerating electrodes. The plurality of extracting orifices is used for extracting an electron beam from the discharge portion into the plasma processing chamber via the compartment. The plurality of extracting orifices is provided radially. The plurality of accelerating electrodes is arranged in the plasma processing chamber. The electron extracting direction from the extracting orifices is set in a substantially parallel direction with an object surface. The number and the arrangement of the accelerating electrodes are set such that a density distribution of the excited plasma has an optimal state for processing the object surface. Objects having a large area can also be processed appropriately.

U.S. Pat. No. 6,692,649 to Collison et al., entitled “Inductively coupled plasma downstream strip module” is directed to a plasma processing module for processing a substrate. The module includes a plasma containment chamber, an inductively coupled source, a secondary chamber and a chamber interconnecting port. The plasma containment chamber includes a feed gas inlet port capable of allowing a feed gas to enter the plasma containment chamber of the plasma processing module during the processing of the substrate. The inductively coupled source is used to energize the feed gas and to strike the plasma within the plasma containment chamber. The specific configuration of the inductively coupled source causes the plasma to be formed such that the plasma includes a primary dissociation zone within the plasma containment chamber. The secondary chamber is separated from the plasma containment chamber by a plasma containment plate. The secondary chamber includes a chuck and an exhaust port. The chuck is configured to support the substrate during the processing of the substrate and the exhaust port is connected to the secondary chamber such that the exhaust port allows gases to be removed from the secondary chamber during the processing of the substrate. The chamber interconnecting port interconnects the plasma containment chamber and the secondary chamber. The chamber interconnecting port allows gases from the plasma containment chamber to flow into the secondary chamber during the processing of the substrate. The chamber interconnecting port is positioned between the plasma containment chamber and the secondary chamber such that when the substrate is positioned on the chuck in the secondary chamber, there is no substantial direct line-of-sight exposure of the substrate to the primary dissociation zone of the plasma formed within the plasma containment chamber.

U.S. Pat. No. 6,418,874 to Cox et al., entitled “Toroidal plasma source for plasma processing” is directed to a toroidal plasma source within a substrate processing chamber. The toroidal plasma source forms a poloidal plasma with theta symmetry. The poloidal plasma current is essentially parallel to a surface of the plasma generating structure thus reducing sputtering erosion of the inner walls. The plasma current is similarly parallel to a process surface of a substrate within the substrate processing chamber. A shaped member located between the substrate and the plasma source controls the plasma density in a selected fashion to enhance plasma processing uniformity. U.S. Pat. No. 6,755,150 to Lai et al., entitled “Multi-core transformer plasma source” is directed to a transformer-coupled plasma source using toroidal cores. The transformer-coupled plasma source forms a plasma with a high-density of ions along the center axis of the torus. The cores of the plasma generator can be stacked in a vertical alignment to enhance the directionality of the plasma and the generation efficiency. The cores can also be arranged in a lateral array into a plasma generating plate that can be scaled to accommodate substrates of various sizes, including very large substrates. The symmetry of the plasma attained allows simultaneous processing of two substrates, one on either side of the plasma generator.

U.S. Pat. No. 5,421,891 to Campbell et al., entitled “High density plasma deposition and etching apparatus” is directed to a plasma deposition and etching apparatus. The apparatus includes a plasma source, a substrate process chamber, an inner magnetic coil and an outer magnetic coil. The plasma source is located above and in an axial relationship to the substrate process chamber. Surrounding the plasma source are the inner magnetic coil and the outer magnetic coil arranged in the same plane perpendicular to the axis of the plasma source and the substrate process chamber. A first current is provided through the inner coil and a second current is provided through the outer coil. The second current is provided in a direction opposite to the direction of the first, current. The magnetic field in the substrate process chamber is thus shaped to achieve an extremely uniform processing. A unique diamond shaped pattern of gas feed lines may be used where the diamond shape is arranged to be approximately tangent at four places to the outer circumference of a workpiece being processed in the apparatus.

U.S. Pat. No. 7,166,816 to Chen et al., entitled “Inductively-coupled toroidal plasma source” is directed to an apparatus for dissociating gases. The apparatus includes a plasma chamber comprising a gas, a first transformer having a first magnetic core, a second transformer having a second magnetic core, a first solid state AC switching power supply, a first voltage supply, a second solid state AC switching power supply and a second voltage supply. The first magnetic core surrounds a first portion of the plasma chamber and has a first primary winding. The second magnetic core surrounds a second portion of the plasma chamber and has a second primary winding. The first solid state AC switching power supply includes one or more switching semiconductor devices which is coupled to the first voltage supply and has a first output that is coupled to the first primary winding. The second solid state AC switching power supply includes one or more switching semiconductor devices which is coupled to the second voltage supply and has a second output that is coupled to the second primary winding. The first solid state AC switching power supply drives a first AC current in the first primary winding. The second solid state AC switching power supply drives a second AC current in the second primary winding. The first AC current and the second AC current induce a combined AC potential inside the plasma chamber that directly forms a toroidal plasma that completes a secondary circuit of the transformer and that dissociates the gas.

U.S. Pat. No. 6,924,455 to Chen et al., entitled “Integrated plasma chamber and inductively-coupled toroidal plasma source” is directed to a material processing apparatus having an integrated toroidal plasma source. The material processing apparatus includes a plasma chamber, a process chamber, a transformer and a solid state AC switching power supply. The plasma chamber comprises a portion of an outer surface of a process chamber. The transformer has a magnetic core which surrounds a portion of the plasma chamber and also includes a primary winding. The solid state AC switching power supply comprises one or more switching semiconductor devices which are coupled to a voltage supply and has an output that is coupled to the primary winding. The solid state AC switching power supply drives an AC current in the primary winding. The AC current in the primary winding induces an AC potential inside the chamber which dissociates a gas inside the chamber, thereby directly forming a toroidal plasma that completes a secondary circuit of the transformer.

### BRIEF DESCRIPTION OF THE DRAWINGS

The disclosed technique will be understood and appreciated more fully from the following detailed description taken in conjunction with the drawings in which:

FIG. 1A is a schematic illustration of a double port side-entry rectangular loop plasma generating system, shown in a side orthogonal view, constructed and operative in accordance with an embodiment of the disclosed technique;

FIG. 1B is a schematic illustration of the double port side-entry rectangular loop plasma generating system of FIG. 1A, shown in a top orthogonal view, constructed and operative in accordance with another embodiment of the disclosed technique;

FIG. 2A is a schematic illustration of a double port side-entry split loop plasma generating system, shown in a top orthogonal view, constructed and operative in accordance with a further embodiment of the disclosed technique;

FIG. 2B is a schematic illustration of an embodiment of the split loop of the double port side-entry split loop plasma generating system of FIG. 2A, shown in a side orthogonal view and a cross-sectional view, constructed and operative in accordance with another embodiment of the disclosed technique;

FIG. 3A is a schematic illustration of a single port side-entry interpenetrating circular loop plasma generating system, shown in a top orthogonal view, constructed and operative in accordance with a further embodiment of the disclosed technique;

FIG. 3B is a simplified schematic illustration of the interpenetrating loop structure of the single port side-entry interpenetrating circular loop plasma generating system of FIG. 3A, constructed and operative in accordance with another embodiment of the disclosed technique;

FIG. 3C is a schematic illustration of a close-up of the interpenetrating circular loop structure of FIG. 3B, constructed and operative in accordance with a further embodiment of the disclosed technique;

FIG. 3D is a schematic illustration of a single port side-entry interpenetrating square loop plasma generating system, shown in a top orthogonal view, constructed and operative in accordance with another embodiment of the disclosed technique;

FIG. 3E is a schematic illustration of a close-up of the interpenetrating square loop structure of FIG. 3D, constructed and operative in accordance with a further embodiment of the disclosed technique;

FIG. 4A is a schematic illustration of a single port side-entry interpenetrating shaft plasma generating system, shown in a top orthogonal view, constructed and operative in accordance with another embodiment of the disclosed technique;

FIG. 4B is a schematic illustration of a double port side-entry interpenetrating double shaft plasma generating system, shown in a top orthogonal view, constructed and operative in accordance with a further embodiment of the disclosed technique;

FIG. 5A is a schematic illustration of a double port top-entry toroidal plasma generating system, shown in a perspective view, constructed and operative in accordance with another embodiment of the disclosed technique;

FIG. 5B is a schematic illustration of the double port top-entry toroidal plasma generating system of FIG. 5A, shown in a side orthogonal view, constructed and operative in accordance with a further embodiment of the disclosed technique;

FIG. 6 is a schematic illustration of a plurality of aperture shapes for emitting plasma constituents, constructed and operative in accordance with another embodiment of the disclosed technique;

FIG. 7A is a schematic illustration of a dielectric gasket inside a high vacuum chamber, constructed and operative in accordance with a further embodiment of the disclosed technique;

FIG. 7B is a schematic illustration of a dielectric gasket outside a high vacuum chamber, constructed and operative in accordance with another embodiment of the disclosed technique;

FIG. 8 is a schematic illustration of an entry-port of the plasma generating system of the disclosed technique, shown in a partial cut-away view, constructed and operative in accordance with a further embodiment of the disclosed technique;

FIG. 9A is a schematic illustration of a roll-to-roll processing plasma generating system, shown in a side orthogonal view, constructed and operative in accordance with another embodiment of the disclosed technique;

FIG. 9B is a schematic illustration of the roll-to-roll processing plasma generating system of FIG. 9A, shown in a top orthogonal view, constructed and operative in accordance with a further embodiment of the disclosed technique;

FIG. 10 is a schematic illustration of another roll-to-roll processing plasma generating system, shown in a side orthogonal view, constructed and operative in accordance with another embodiment of the disclosed technique;

FIG. 11A is a simplified schematic illustration of another roll-to-roll processing plasma generating system, shown in a perspective view, constructed and operative in accordance with a further embodiment of the disclosed technique;

FIG. 11B is a simplified schematic illustration of a further roll-to-roll processing plasma generating system, shown in a perspective view, constructed and operative in accordance with another embodiment of the disclosed technique; and

FIG. 11C is a simplified schematic illustration of another roll-to-roll processing plasma generating system, shown in a top orthogonal view, constructed and operative in accordance with a further embodiment of the disclosed technique.

### DETAILED DESCRIPTION OF THE EMBODIMENTS

The disclosed technique overcomes the disadvantages of the prior art by providing a novel system for generating plasma. The system of the disclosed technique generates and supplies low energy, crude plasma constituents to a target located in a high vacuum processing chamber. When supplied to the high vacuum processing chamber, the crude plasma constituents are proximate to the target. The system of the disclosed technique includes a plasma discharge chamber which physically penetrates into a high vacuum processing chamber and sprays plasma onto a target from a relatively short distance. The plasma discharge chamber (herein abbreviated DCh) operates at low vacuum conditions and forms a closed loop. The closed loop DCh substantially forms a single secondary loop around ferrite cores in a transformer-type plasmatron. Conductors are coiled around the other sides of the ferrite cores, the conductors being coupled with an AC power supply operating at a low RF frequency. According to the disclosed technique, the closed loop DCh is constructed and designed to facilitate insertion and removal of the closed loop DCh from a high vacuum processing chamber (herein abbreviated PCh). The closed loop DCh may be tubular in structure. The design of the DCh of the disclosed technique enables the DCh to be coupled with existing prior art PChs. In addition, the closed loop DCh is constructed and designed to physically penetrate the PCh such that a portion of the DCh is in close proximity to the position of the processing target in the PCh. According to the disclosed technique, the portion of the DCh in close proximity to the position of the processing target is provided with a plurality of apertures for uniformly spraying the processing target with the generated plasma in the DCh.

In general, the disclosed technique relates to the generation of plasma for executing various chemical processes in high vacuum processing chambers. High vacuum processing chambers can also be referred to as high vacuum reaction chambers. In general, the plasma generated according to the disclosed technique is plasma which has not undergone any filtering. Such unfiltered plasma, also known as crude plasma, may include various types of plasma constituents such as ions, free radicals and free electrons as well as neutral atoms and molecules. The term ‘plasma’ is used throughout the description of the disclosed technique to refer to crude plasma as just described. It is noted that many chemical and physical processes performed at high and ultrahigh vacuum conditions can be effectively executed when supplied with low energy reactants. According to the disclosed technique, low energy reactants are supplied to a target in a high or ultrahigh vacuum chamber by maintaining plasma constituents (i.e., the reactants) in low electrical fields, having the reactants exit a DCh into the high vacuum chamber in close proximity to a processing target while maintaining a large Knudsen number in the vacuum chamber. As described below, according to the disclosed technique the DCh can be coupled with and used with high vacuum batch wafer processing chambers as well as high vacuum roll-to-roll processing chambers.

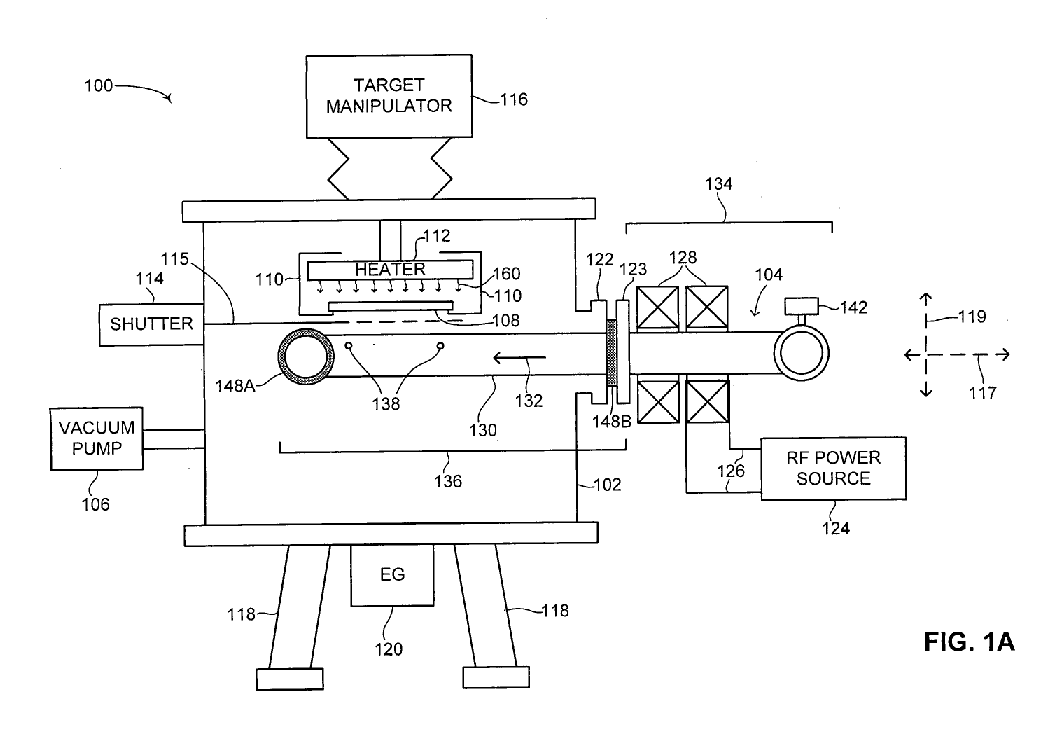

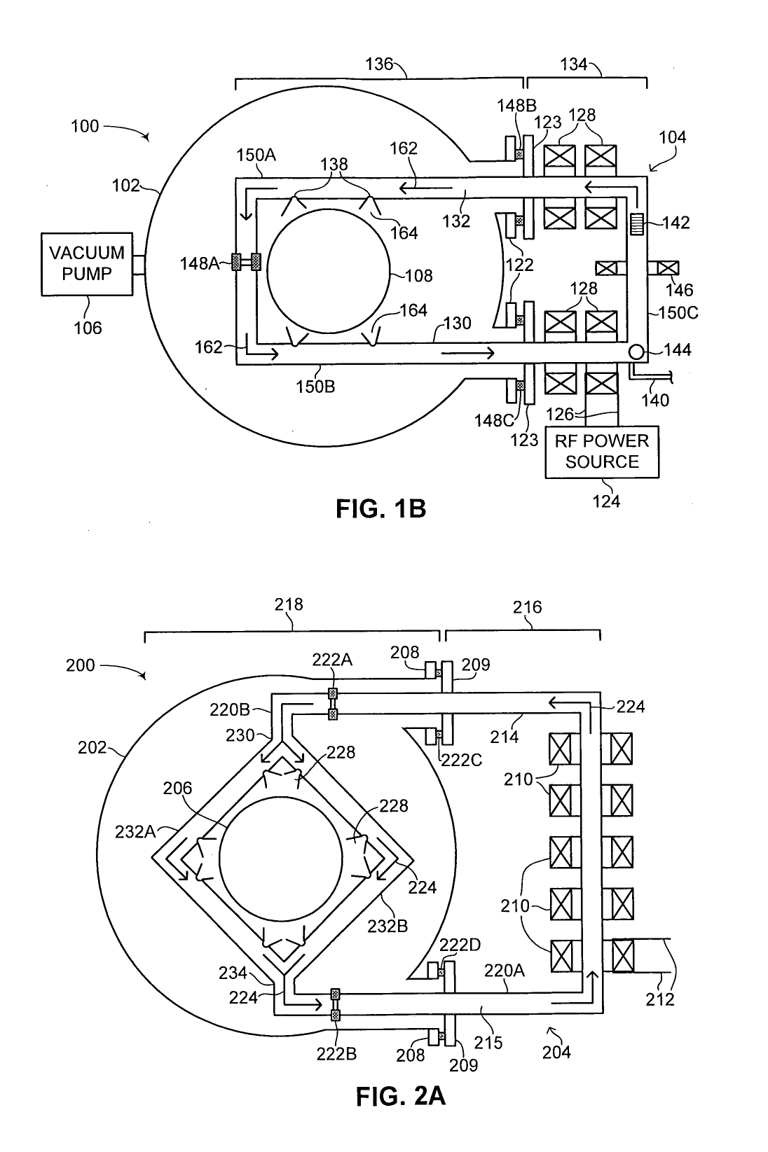

Reference is now made to FIG. 1A, which is a schematic illustration of a double port side-entry rectangular loop plasma generating system, shown in a side orthogonal view, generally referenced 100, constructed and operative in accordance with an embodiment of the disclosed technique. The side orthogonal view of FIG. 1A is substantially a cross-sectional view of double port side-entry rectangular loop plasma generating system 100 as its internal elements are visible. Double port side-entry rectangular loop plasma generating system 100 (herein referenced as rectangular loop plasma generating system 100) includes a PCh 102 and a transformer-type plasmatron 104. PCh 102 is substantially a high vacuum processing chamber in which high vacuum conditions are maintained. Transformer-type plasmatron 104 is coupled with PCh 102. As described below in greater detail, a portion of transformer-type plasmatron 104 is inserted into PCh 102. In general rectangular loop plasma generating system 100 is used to generate plasma which can then be used for chemical processes occurring in a high vacuum environment. Transformer-type plasmatron 104 substantially generates a plasma which is then introduced into PCh 102, where the plasma may be used for chemical processes occurring in PCh 102.

PCh 102 includes a high vacuum pump 106, a target 108, a target holder 110, a target heater 112, a shutter 114, a target manipulator 116, at least one Knudsen cell evaporation source 118, an electron gun evaporator 120, two entry-ports 122. PCh 102 may also include a pressure gauge (not shown), a mass spectrometer (not shown) and a reflective high energy electron diffraction (herein abbreviated RHEED) tool (not shown) as is known in high vacuum reaction chambers. PCh 102 may additionally include a target transport mechanism (not shown), an infrared pyrometer (not shown), a film thickness monitor (not shown), a film deposition controller (not shown), an ion source (not shown), an ellipsometer (not shown) and a plurality of gas sources (all not shown). PCh 102 may further include other known elements that are generally used in high vacuum processes.

PCh 102 is substantially a compartment which can be hermetically sealed. PCh 102 may be shaped like a cylinder, cube, sphere or any other known shape. PCh 102 is usually made of stainless steel. PCh 102 may be a barrel-type processing chamber, having for example, a volume ranging from 40 to 4000 liters. High vacuum pump 106, shutter 114, target manipulator 116, the at least one Knudsen cell evaporation source 118 and electron gun evaporator 120 are all coupled with PCh 102 from the outside. Target 108, target holder 110 and target heater 112 are all substantially coupled with PCh 102 from the inside. High vacuum pump 106 pumps air out of PCh 102 thereby generating and maintaining high vacuum conditions within PCh 102. For example, the pressure in PCh 102 after high vacuum pump 106 pumps air out of PCh 102 may be between 10⁻⁴-10⁻¹⁰ Pa. Target 108 substantially represents a target on which a chemical reaction can occur. Target 108 may be a wafer, a film, a fiber and the like, and may measure up to 20 centimeters, for example. Target holder 110 substantially holds target 108 in place. As shown in FIG. 1A, target holder 110 holds target 108 at its edges thereby not obstructing target 108 from chemicals, elements and plasma which may be directed at target 108. Target heater 112 is substantially positioned above target 108 and is used to increase the surface temperature of target 108. Heat provided by target heater 112 to target 108 is shown in FIG. 1A by a plurality of arrows 160.

Shutter 114 substantially includes an arm 115 which can be extended into PCh 102 to cover target 108. Arm 115 can be used to cover and shield target 108 from reactants coming from at least one Knudsen cell evaporation source 118, electron gun evaporator 120 or plasma present in PCh 102. Target manipulator 116 can be used to move target 108, target holder 110 and target heater 112 in a plurality of directions, such as up and down, as well as to angle and rotate any one of target 108, target holder 110 and target heater 112 to enable equalization of deposition. The at least one Knudsen cell evaporation source 118 is used to provide vapors from elements into PCh 102. Each of the Knudsen cell evaporation sources 118 shown in FIG. 1A are positioned such that elements evaporated by them and provided to PCh 102 are directed to impinge and deposit substantially on a majority of the surface of target 108. A plurality of additional Knudsen cell evaporation sources (not shown) may be coupled with PCh 102 and directed towards target 108 such that elements provided to PCh 102 via the plurality of Knudsen cell evaporation sources substantially impinge and deposit evenly on the entire surface of target 108. Electron gun evaporator 120 is also coupled with PCh 102 and positioned such that metal vapors provided by electron gun evaporator 120 to PCh 102 substantially impinge and deposit evenly over substantially a majority of the surface of target 108. Two entry-ports 122 are coupled with the side of PCh 102. Entry-ports 122 are shown more clearly below in FIG. 1B. As described below, entry-ports 122 enable transformer-type plasmatron 104 to penetrate into PCh 102.

Transformer-type plasmatron 104 includes a connection flange 123, a radio frequency (herein abbreviated RF) power source 124, a plurality of conductors 126, a plurality of high permeability magnetic cores 128, a closed loop discharge chamber (herein abbreviated “closed loop DCh” or simply “DCh”) 130, a plurality of apertures 138, a capacitance pressure gauge 142 and a dielectric gaskets 148A and 148B. Connection flange 123 is coupled with entry-ports 122 via dielectric gasket 148B. Transformer-type plasmatron 104 includes additional elements shown only in FIG. 1B and elaborated on in the description of FIG. 1B. Transformer-type plasmatron 104 further includes an impedance matching network coupled with RF power source 124. Within closed loop DCh 130, a plasma is generated as indicated by an arrow 132. It is noted that arrow 132 is drawn to show that the plasma generated in closed loop DCh 130 forms a closed loop and not to describe that the plasma flows in a particular direction. Closed loop DCh 130 is substantially a low vacuum discharge chamber, maintaining a pressure substantially between 0.1-10 Pa. Closed loop DCh 130 has a rectangular shape, shown more clearly below in FIG. 1B. Closed loop DCh 130 is functionally divided into two sections, an outer section 134 and an inner section 136. Inner section 136 is inserted into PCh 102 via entry-ports 122, while outer section 134 remains outside PCh 102. Outer section 134 is where plasma 132 is generated while inner section 136 is where plasma 132 is released into PCh 102. RF power source 124 is coupled with plurality of conductors 126. Plurality of conductors 126 are coupled with plurality of high permeability magnetic cores 128. Although not explicitly shown in FIG. 1A, each one of plurality of high permeability magnetic cores 128 is coupled with a respective one of plurality of conductors 126. Plurality of conductors 126 are wound around plurality of high permeability magnetic cores 128, thereby forming the primary winding in transformer-type plasmatron 104. Plurality of high permeability magnetic cores 128 substantially surround closed loop DCh 130. Closed loop DCh 130 substantially forms the secondary winding in transformer-type plasmatron 104. Each one of plurality of apertures 138 is substantially located on inner section 136 of closed loop DCh 130. Plurality of apertures 138 can also be referred to as a plurality of orifices or nozzles. Plurality of apertures 138 release plasma 132 from inner section 136 into PCh 102, substantially onto target 108.

Inner section 136 is designed to extend into PCh 102 such that it surrounds target 108 (shown more clearly in FIG. 1B). Inner section 136 and target 108 are positioned in PCh 102 such that inner section 136 is positioned slightly below target 108. For example, inner section 136 may be positioned a few centimeters below target 108, such as between 2 to 10 centimeters below target 108. As inner section 136 of closed loop DCh 130 has a rectangular shape, inner section 136 does not obstruct target 108 from elements provided to PCh 102, for example in vapor form, from at least one Knudsen cell evaporation source 118 and electron gun evaporator 120. It is noted that the exact position of inner section 136 in relation to target 108 is a matter of design choice and substantially represents a trade-off between the measured pressure inside DCh 130 (measured via capacitance pressure gauge 142), the measured current of plasma 132 inside DCh 130 (measured by a magnetic ring current gauge positioned around DCh 130—not shown) and the homogeneity of the spread of plasma 132 on target 108.

Plurality of apertures 138 is positioned in proximity to target 108 and at angle relative to target 108 such that plasma 132, which is released by inner section 136 via plurality of apertures 138, is emitted substantially evenly over the surface of target 108. As shown in greater detail below in FIG. 1B, plurality of apertures 138 are placed symmetrically around target 108 such that plasma 132 sprays evenly over the surface of target 108. Each one of plurality of apertures 138 is positioned at a distance relative to target 108 which is substantially shorter than the mean free path distance of the plasma constituents in plasma 132. The mean free path distance of a plasma represents the distance over which constituents of the plasma can travel before substantially annihilating, for example, by recombining with one another. By positioning plurality of apertures 138 at a distance to target 108 which is less than the mean free path distance of plasma 132, plasma constituents of plasma 132 can substantially impinge and deposit on the surface of target 108. As plasma 132 is released via plurality of apertures 138, plasma 132 forms a plume in PCh 102 in the direction of target 108. The angle of plurality of apertures 138 relative to target 108 is such that the plume released from each one of plurality of apertures 138 forms an elliptical projection on the surface of target 108. The concentration of plasma constituents is highest closer to plurality of apertures 138 and gradually lessens towards the center of target 108. Each one of plurality of apertures 138 is thus positioned on closed loop DCh 130 such that respective adjacent elliptical projections formed by different ones of plurality of apertures 138 on the surface of target 108 overlap and form a substantially homogeneous spread of plasma constituents from plasma 132 on target 108.

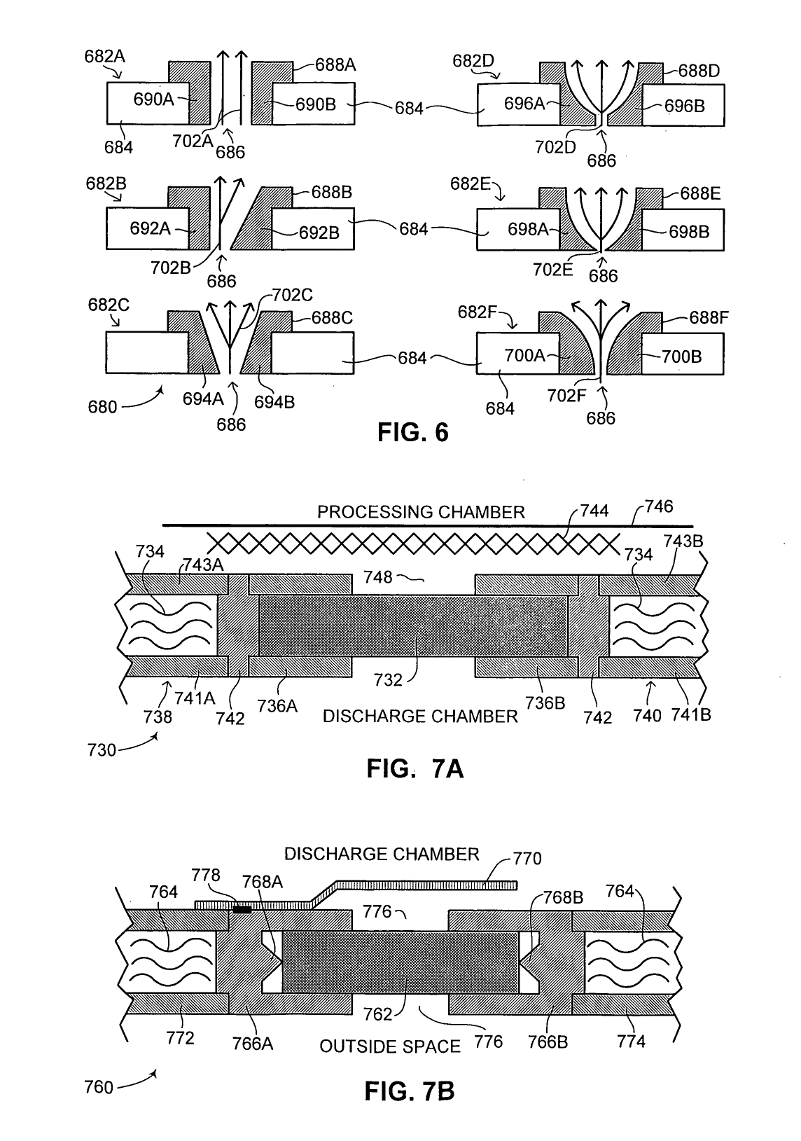

Plurality of apertures 138 each have a diameter ranging from approximately 1-8 mm, depending on the actual number of plurality of apertures 138 in DCh 130 and the Knudsen number (herein abbreviated Kn) of rectangular loop plasma generating system 100, in order to not spoil the high vacuum conditions in PCh 102. A respective sleeve (not shown), having an opening at each end, is inserted into each one of plurality of apertures 138. Each respective sleeve is therefore inserted into one of the walls of DCh 130 via plurality of apertures 138. An outer diameter of each respective sleeve is substantially equivalent to the diameter of plurality of apertures 138. Each respective sleeve functions as a nozzle for releasing and directing plasma 132 at target 108. Each sleeve may be directed at a particular angle towards target 108. In general, the opening in the sleeve facing target 108 (i.e., the nozzle end of the sleeve) is not substantially circular in cross-sectional shape and is not directed in a perpendicular direction to a major axis 117 or a minor axis 119 of DCh 130. The nozzle end of the sleeve may have a cross-sectional shape in any suitable geometrical form, such as a cylinder, a cone, an ellipse, a parabola, a hyperbola and the like, with the larger dimension of the cross-sectional shape (for example, the major axis of an ellipse) being directed towards target 108. The specific cross-sectional shape of the nozzle end of the sleeve can change the size and spread of the elliptical projection of the plume of plasma 132 released from the nozzle end of the sleeve. Various shapes and forms of the sleeve are shown in greater detail below in FIG. 6. In general, the nozzle ends of the various sleeves inserted into plurality of apertures 138 are directed radially towards target 108.

The distance between each one of plurality of apertures 138 and the number of apertures 138 included in DCh 130 depend on the size of target 108, the distance from the respective nozzle ends of the sleeves inserted into plurality of apertures 138 to target 108 and the dimensions and shape of the nozzle ends of the sleeves. In general, the distance between adjacent ones of plurality of apertures 138 should be substantially similar to the distance between a given one of plurality of apertures 138 and target 108. Also, as target 108 increases in size, the distance between adjacent ones of plurality of apertures 138 increases accordingly. Each respective sleeve can be produced from one of the following materials: refractory metals, such as tungsten (W), tantalum (Ta) or molybdenum (Mo), ceramics, silica glass, pyrolytic boron nitride (PBN) and graphite. Each respective sleeve may measure approximately 5-10 mm in length and may have a diameter ranging between 5-20 mm on the opening facing away from target 108 (i.e., not the nozzle end of the sleeve).

Reference is now made to FIG. 1B, which is a schematic illustration of the double port side-entry rectangular loop plasma generating system of FIG. 1A, shown in a top orthogonal view, also generally referenced 100, constructed and operative in accordance with another embodiment of the disclosed technique. Equivalent elements in FIGS. 1A and 1B are labeled using identical numbers. A number of elements from FIG. 1A are purposefully omitted in FIG. 1B in order to better show and explain additional elements of rectangular loop plasma generating system 100. Shown in FIG. 1B as shown in FIG. 1A are PCh 102, transformer-type plasmatron 104, vacuum pump 106, target 108, two entry-ports 122, connection flange 123, RF power source 124, plurality of conductors 126, plurality of high permeability magnetic cores 128, closed loop DCh 130, plurality of apertures 138, capacitance pressure gauge 142 and dielectric gaskets 148A and 148B. Plasma 132 is substantially located all around DCh 130, as shown by a plurality of arrows 162. It is noted that plurality of arrows 162 merely shows that plasma 132 inside DCh 130 forms a closed loop. Plasma 132 does not actually travel around DCh 130. Target 108 has a circular shape in FIG. 1B. Target 108 can also have any suitable shape, such as a rectangular shape and is a matter of design choice. Also, seen more clearly in FIG. 1B are outer section 134 of DCh 130 and inner section 136 of DCh 130. Inner section 136 penetrates into PCh 102, whereas outer section 134 remains outside PCh 102. In addition, as can only be seen in FIG. 1B, rectangular loop plasma generating system 100 also includes a gas inlet leaking valve 140, a view port 144, a magnetic ring current gauge 146 and three dielectric gaskets 148A, 148B and 148C. Gas inlet leaking valve 140, capacitance pressure gauge 142, view port 144 and magnetic ring current gauge 146 are all positioned in outer section 134. Gas inlet leaking valve 140 is coupled to a gas cylinder (not shown). Capacitance pressure gauge 142 and view port 144 are both coupled with DCh 130. Magnetic ring current gauge 146 is substantially a transformer ring core placed around DCh 130. In addition, rectangular loop plasma generating system 100 may also include a wire loop (not shown), substantially parallel to and following the path of DCh 130. In particular the wire loop is parallel to the path of DCh 130 at plurality of high permeability magnetic cores 128, such that an additional secondary winding is formed around plurality of high permeability magnetic cores 128 to measure the maintenance voltage.

Gas inlet leaking valve 140 enables gas to fill DCh 130. The gas which fills DCh 130 from gas inlet leaking valve 140 is the gas which will be ignited into plasma 132 when voltage and power are provided to plurality of high permeability magnetic cores 128. Capacitance pressure gauge 142 substantially measures the pressure inside DCh 130. View port 144 enables a user to view the generation of plasma 132 inside outer section 134 and optionally conduct spectroscopic analysis of the plasma. Magnetic ring current gauge 146 measures the current along DCh 130. The wire loop (not shown) is used to measure the voltage produced by rectangular loop plasma generating system 100 over the secondary winding of the system, which is substantially plasma 132 inside DCh 130. Voltage is measured across the wire loop. Since the wire loop substantially follows the same path as DCh 130, the voltage across the wire loop represents the voltage inside DCh 130.

As shown in FIG. 1B, transformer-type plasmatron 104 is inserted and coupled with PCh 102 via the two entry-ports 122. Two entry-ports 122 must be tightly sealed in order to maintain the high vacuum conditions within PCh 102. Entry-ports 122 may be sealed by Teflon® rings, such as dielectric gaskets 148B and 148C, as shown in FIG. 1B. Plurality of conductors 126 form the primary winding of transformer-type plasmatron 104 around plurality of high permeability magnetic cores 128. Plasma 132, located inside DCh 130, forms the secondary winding of transformer-type plasmatron 104. Gas is leaked into DCh 130 via gas inlet leaking valve 140 and power is supplied to plurality of high permeability magnetic cores 128 via plurality of conductors 126. The power supplied to plurality of high permeability magnetic cores 128 induces an alternating magnetic field in plurality of high permeability magnetic cores 128 which in turn induces an alternating electric field in DCh 130. The induced alternating electric field in DCh 130 is used to dislodge electrons from atoms and molecules in the gas, thereby igniting the gas into plasma 132. The induced alternating electric field in DCh 130 is also used to maintain plasma 132. As plasma 132 is sustained in DCh 130, a small amount of plasma 132 is released into PCh 102 via plurality of apertures 138. Due to the spatial location and the shape of plurality of apertures 138, plasma 132 is released into PCh 102 in the form of a plurality of plumes 164 in the direction of target 108. As seen, plurality of apertures 138 is placed at different locations along DCh 130 in order that plasma 132 deposits evenly over the surface of target 108. In general, plurality of apertures 138 are placed symmetrically (e.g., at identical distances from the surface of target 108) along DCh 130 such that an even spread of plasma 132 is achieved over the surface of target 108.

In order for the gas introduced into DCh 130 to ignite and conduct into plasma 132, the walls of DCh 130 must be non-conductive; otherwise the induced voltage and current will pass through the walls of DCh 130 and no plasma will be formed. DCh 130 is therefore separated into a plurality of electrically isolated sections. In the example in FIGS. 1A and 1B, DCh 130 is separated into three electrically isolated sections 150A, 150B and 150C. Electrically isolated sections 150A and 150B substantially represent inner section 136 of DCh 130 and electrically isolated section 150C substantially represents outer section 134 of DCh 130. Each of electrically isolated sections 150A, 150B and 15C is substantially an open metal tube. Electrically isolated sections 150A, 150B and 150C are coupled together, yet electrically separated from one another, by dielectric gaskets 148A, 148B and 148C. Dielectric gaskets 148A, 148B and 148C are used for sealing in an electrically isolated manner, electrically isolated sections 150A, 150B and 150C. Dielectric gaskets 148A, 148B and 148C are made from a soft material, such as Teflon®, and are sandwiched between two rigid flanges. For example, dielectric gaskets 148B and 148C are sandwiched between connection flanges 123 and entry-ports 122. Dielectric gasket 148A couples electrically isolated sections 150A and 150B. Dielectric gasket 148B couples electrically isolated sections 150A and 150C. Dielectric gasket 148C couples electrically isolated sections 150B and 150C. Dielectric gaskets 148A, 148B and 148C are explained in greater detail below in FIGS. 7A and 7B. In general it is noted that throughout the description, tube ends of a DCh which are coupled via a dielectric gasket, for example, the tube ends of electrically isolated sections 150A and 150B which are coupled with dielectric gasket 148A, substantially form a capacitor due to a difference in potential between the tube ends. Due to the presence of dielectric gaskets 148A, 148B and 148C in DCh 130, each of electrically isolated sections 150A, 150B and 150C may be at a different electrical potentials when plasma 132 conducts.

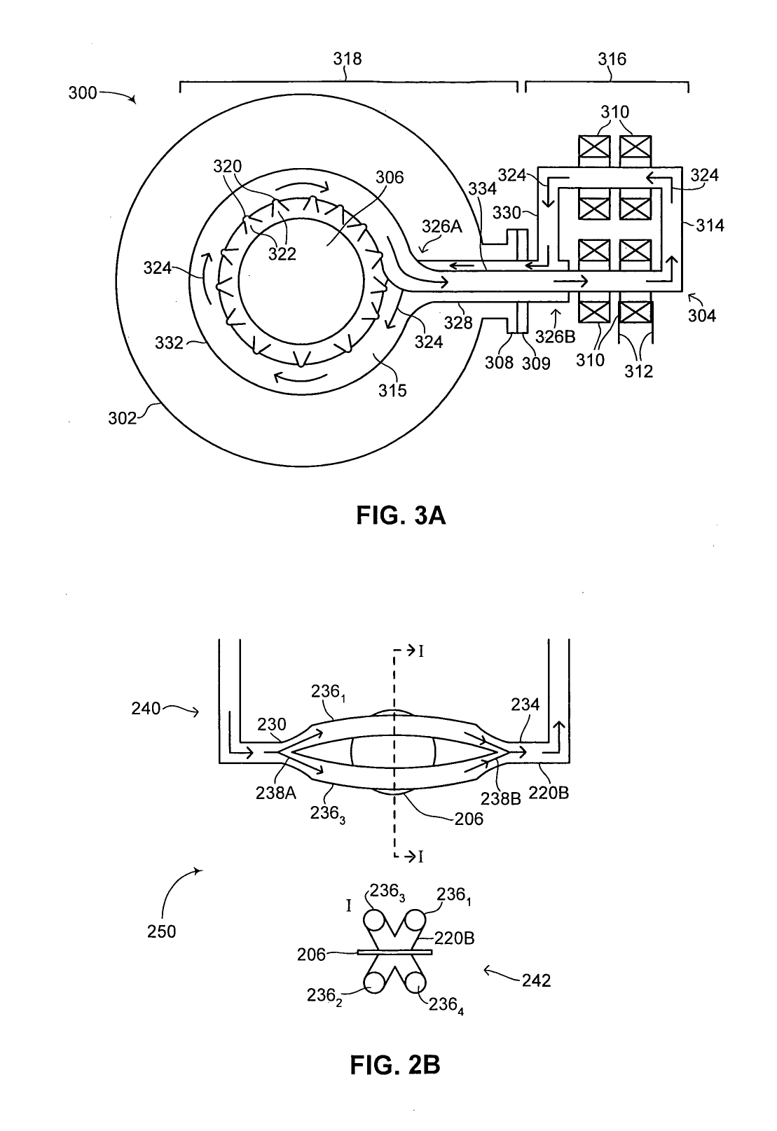

According to the disclosed technique, DCh 130 may be divided into a plurality of electrically isolated sections. The various electrically isolated sections can separate DCh 130 at suitable position along DCh 130, for example in order to ease the assembly and disassembly of DCh 130 from PCh 102 via entry-ports 122. As an example, DCh 130 may be divided into four electrically isolated sections, with dielectric gasket 148A being replaced by two dielectric gaskets (not shown), each one being respectively parallel to dielectric gaskets 148B and 148C, positioned along either long side of DCh 130. As another example, DCh 130 may be divided into two electrically isolated sections, with dielectric gaskets 148B and 148C being replaced by a single dielectric gasket (not shown), positioned along DCh 130 substantially opposite dielectric gasket 148A, adjacent to the position magnetic ring current gauge 146 as shown in FIG. 1B. In such an example a plurality of small diameter high permeability magnetic cores (not shown) can be positioned along the short side of DCh 130 (instead of plurality of high permeability magnetic cores 128) and the overall length of DCh 130 can be shortened. As shown in FIG. 1B, DCh 130 has a rectangular form and enters PCh 102 via two entry-ports 122. As described below in FIGS. 2A, 3A, 3D, 4A, 4B, 5A and 5B, the closed loop DCh of the disclosed technique can have other forms and shapes besides the rectangular form shown in FIG. 1B.

Each of electrically isolated sections 150A, 150B and 150C is constructed from double-walled water-cooled stainless steel tubing, as is commonly used in high vacuum chamber technology. Each of electrically isolated sections 150A, 150B and 150C may further include a plurality of inlet pipes (not shown) and outlet pipes (not shown) for circulating the coolant (i.e., water) between the double walls of the tubing. The inlet pipes (not shown) may be placed along the inside walls (not shown) of DCh 130 or along the outside walls (not shown) of DCh 130 without disrupting the electric potential of a respective electrically isolated section. The inlet pipes and the outlet pipes carrying the coolant may be extended outside PCh 102 by plastic pipes (not shown). The inner diameter of the tubing of each electrically isolated section 150A, 150B and 150C is larger than the mean free path distance of the plasma constituents in plasma 132 at a pressure of between 0.1-1 Pa inside PCh 102. For example, the inner diameter of the tubing of electrically isolated section 150A may be approximately 40 mm.

In general, the length of tubing used for electrically isolated section 150C, which is located in outer section 134, is reduced as much as possible in order to lower the overall voltage induced in DCh 130, as a high voltage in DCh 130 may induce sputtering of the walls of DCh 130, thus increasing contamination in DCh 130 which may affect the quality of deposition of plasma 132 on target 108. In general, since DCh 130 is substantially a conductor, reducing its length reduces its resistivity according to Ohm's law, thereby reducing the amount of power required to maintain the maintenance voltage of plasmas 132 and thus the voltage induced in DCh. The length of electrically isolated section 150C is substantially determined by the dimensions and geometry of plurality of high permeability magnetic cores 128 as well as how many high permeability magnetic cores 128 are used in rectangular loop plasma generating system 100. As electrically isolated section 150C has a substantially “U”-based shape, plurality of high permeability magnetic cores 128 may be placed on the base of electrically isolated section 150C (i.e., where magnetic ring current gauge 146 is located) to reduce the length of tubing in electrically isolated section 150C. The length of tubing used for electrically isolated sections 150A and 150B is substantially determined according to the size, shape and geometry of target 108. Corners or sharp angles in the shape of electrically isolated sections 150A and 150B may be curved or trimmed in order to reduce local electric fields present in sharp edges of DCh 130 as well as the overall length of tubing used in these electrically isolated sections. In general, local electric fields are prone to cause sputtering and to add contamination to the walls of DCh 130.

It is noted that in general, transformer-type plasmatron 104 is electrically separated from PCh 102. In principle though, one of electrically isolated sections 150A, 150B or 150C can be electrically grounded with PCh 102. In addition, DCh 130 may be a loop with only one isolated separation, having only a single dielectric gasket (not shown). However, in such a setup a substantially high electric field, for example on the order of a few kilovolts per cm, may develop in the vicinity of the single dielectric gasket. Such a substantially high electric field may be generated when plasma 132 is initially ignited and may break the dielectric gasket, thereby disrupting the electrical separation between the two electrically isolated sections of DCh 130 (not shown). Disruption of a dielectric gasket at high electric fields is related to the strength of the electric field, the type of dielectric material from which the dielectric gasket is produced from, the cross-sectional area of the dielectric gasket, which is related to the formation of the high electric field and the cleanliness and the integrity of the dielectric gasket.

Reference is now made to FIG. 2A, which is a schematic illustration of a double port side-entry split loop plasma generating system, shown in a top orthogonal view, generally referenced 200, constructed and operative in accordance with a further embodiment of the disclosed technique. Double port side-entry split loop plasma generating system 200 (herein referred to as split loop plasma generating system 200) includes a PCh 202, a transformer-type plasmatron 204 and a target 206. PCh 202 is maintained at high vacuum conditions, whereas transformer-type plasmatron 204 is maintained at low vacuum conditions. Split loop plasma generating system 200 is substantially similar to rectangular loop plasma generating system 100 (FIGS. 1A and 1B) and includes many of the same elements of rectangular loop plasma generating system 100. In general, the main difference between split loop plasma generating system 200 and rectangular loop plasma generating system 100 is the shape of the transformer-type plasmatron inserted into the PCh. In order to better explain the disclosed technique, similar elements between split loop plasma generating system 200 and rectangular loop plasma generating system 100 have been omitted, such as a target holder, a target heater, a shutter, a target manipulator, a plurality of Knudsen cell evaporation sources, an electron gun evaporator, a gas inlet leaking valve, a capacitance pressure gauge, a view port, a magnetic ring current gauge and the like.

PCh 202 includes two entry-ports 208. Transformer-type plasmatron 204 includes a connection flange 209, a plurality of high permeability magnetic cores 210 (herein referred to as ferrite cores 210), a plurality of conductors 212, a split loop DCh 214 (herein referred to as either “split loop DCh” or simply “DCh”), dielectric gaskets 222A, 222B, 222C and 222D and a plasma 215. Ferrite cores 210 are positioned around DCh 214. Plurality of conductors 212 are coupled with each one of ferrite cores 210 (not explicitly shown in FIG. 2A). Plurality of conductors 212 are coupled with a low RF power source and an impedance matching network (not shown). Split loop DCh 214 is functionally divided into two sections, an outer section 216 and an inner section 218. Inner section 218 is inserted into PCh 202 via entry-ports 208, while outer section 216 remains outside PCh 202. Outer section 216 is where plasma 215 is generated while inner section 218 is where plasma 215 is released into PCh 202. Plasma 215 forms a closed loop around DCh 214, as shown by a plurality of arrows 224. DCh 214 includes two electrically isolated sections 220A and 220B. Electrically isolated sections 220A and 220B are coupled via dielectric gaskets 222A and 222B, which electrically separate the two sections from one another. Dielectric gaskets 222A and 222B are substantially similar in construction, material, installation and operation to dielectric gasket 148A (FIGS. 1A and 1B), and are further described below in FIG. 7A. Electrically isolated section 220A is substantially similar to electrically isolated section 150C. The portions of electrically isolated section 220A which are inserted into entry-ports 208 may be sealed with Teflon® rings, such as dielectric gaskets 222C and 222D.

Electrically isolated section 2206 has a substantially split shape, resembling a parallelogram. Electrically isolated section 220B splits into two channels 232A and 232B at a first point 230. Channels 232A and 232B recombine into a single channel at a second point 234. Along channels 232A and 232B, electrically isolated section 220B includes a plurality of apertures 226 for releasing plasma 215 into PCh 202 to be deposited on target 206. As shown in FIG. 2A, each one of plurality of apertures 226 releases plasma 215 into PCh 202 in the form of a respective plume 228. Plurality of apertures 226 substantially resemble plurality of apertures 138 (FIGS. 1A and 1B) and may have sleeves (not shown) inserted into them, wherein the end of each sleeve facing target 206 functions as a nozzle (not shown). Channels 232A and 232B are substantially similar and substantially symmetrical such that plasma 215 inside DCh 214 evenly splits at first point 230 into channels 232A and 232B. Channels 232A and 232B split from first point 230 and recombine at second point 234 at substantially identical angles. Channels 232A and 232B are substantially identical in terms of shape, diameter and length and are substantially mirror images of one another. By making channels 232A and 232B substantially identical, plasma 215 will substantially ignite equally in both channels. In addition, plasma 215 released via plurality of apertures 226 will have substantially identical plasma constituents as plasma 215 deposits on target 206. Plurality of apertures 226 are spaced substantially evenly and symmetrically along channels 232A and 232B, such that the amount of plasma 215 released onto target 206 from each aperture is substantially equal. In this regard, plurality of apertures 226 releases plasma 215 into PCh 202 towards target 206 substantially uniformly on target 206. As compared with closed loop DCh 130 (FIGS. 1A and 1B), split loop DCh 214 may provide a more uniform spread and deposit of plasma 215 on target 206 due to its symmetrical shape and positioning around target 206.

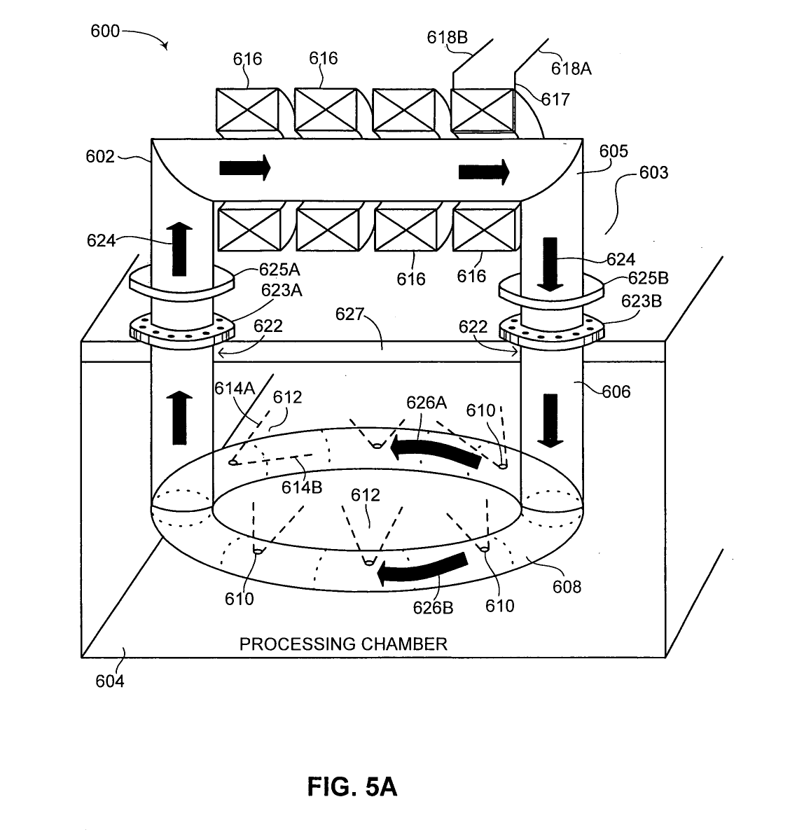

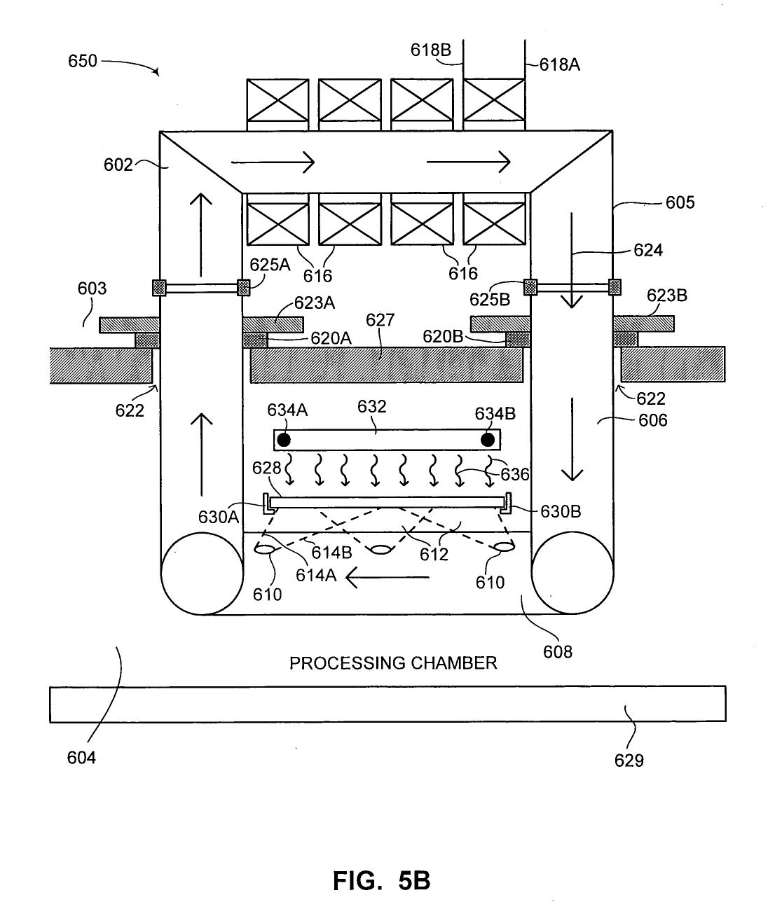

The general shape of electrically isolated section 220B enables a uniform spread and deposit of plasma 215 on target 206. Target 206 as shown in FIG. 2A is substantially flat and has a circular shape. Target 206 is in general flat, yet in cross-section (as shown in FIG. 2A), target 206 can have a plurality of shapes and dimensions. For example, target 206 may have a cross-sectional shape which is a cylinder, an ellipse and the like. Target 206 may also not be flat and may have, for example, a cylindrical or spherical shape. It is noted that the split shape of electrically isolated section 220B can be adapted to the various shapes and dimensions of target 206. In general, at first point 230, electrically isolated section may split into a plurality of different channels, provided that each channel is substantially identical in terms of topology, diameter and length. The split shape of electrically isolated section 220B can substantially be any closed symmetric shape, such as a circle, square, rhombus, ellipse, parallelogram, polygon and the like. In addition, the plane formed by electrically isolated section 220B can have substantially any angle with respect to the plane formed by electrically isolated section 220A. For example, in FIGS. 5A and 5B below, a double port top-entry split loop plasma generating system is shown where the split section of the DCh has a circular shape and is at right angles to the section of the DCh which is inserted into the PCh.

Reference is now made to FIG. 2B, which is a schematic illustration of an embodiment of the split loop of the double port side-entry split loop plasma generating system of FIG. 2A, shown in a side orthogonal view and a cross-sectional view, generally referenced 250, constructed and operative in accordance with another embodiment of the disclosed technique. The side orthogonal view of split loop 250 is generally referenced 240 and the cross-sectional view of split loop 250 is generally referenced 242. Cross-sectional view 242 is a cross-sectional view of side orthogonal view 240 along the dotted line labeled as ‘I.’Similar elements between FIGS. 2B and 2A are labeled using identical numbers. An embodiment of electrically isolated section 220B is shown in FIG. 2B wherein electrically isolated section 220B splits into four channels 236₁, 236₂, 236₃ and 236₄ at first point 230. Since each of channels 236₁, 236₂, 236₃ and 236₄ are substantially identical in terms of geometry, diameter, length and the angle at which they split off from first point 230, as indicated by a plurality of arrows 238A, and at which they recombine at second point 234, as indicated by a plurality of arrows 238B, plasma (not shown) in each of channels 236₁, 236₂, 236₃ and 236₄ substantially uniformly deposits on both sides of target 206, as shown in cross-sectional view 242. As is obvious to one skilled in the art, many other embodiments of split loop 250 are possible according to the disclosed technique and are a matter of design choice.

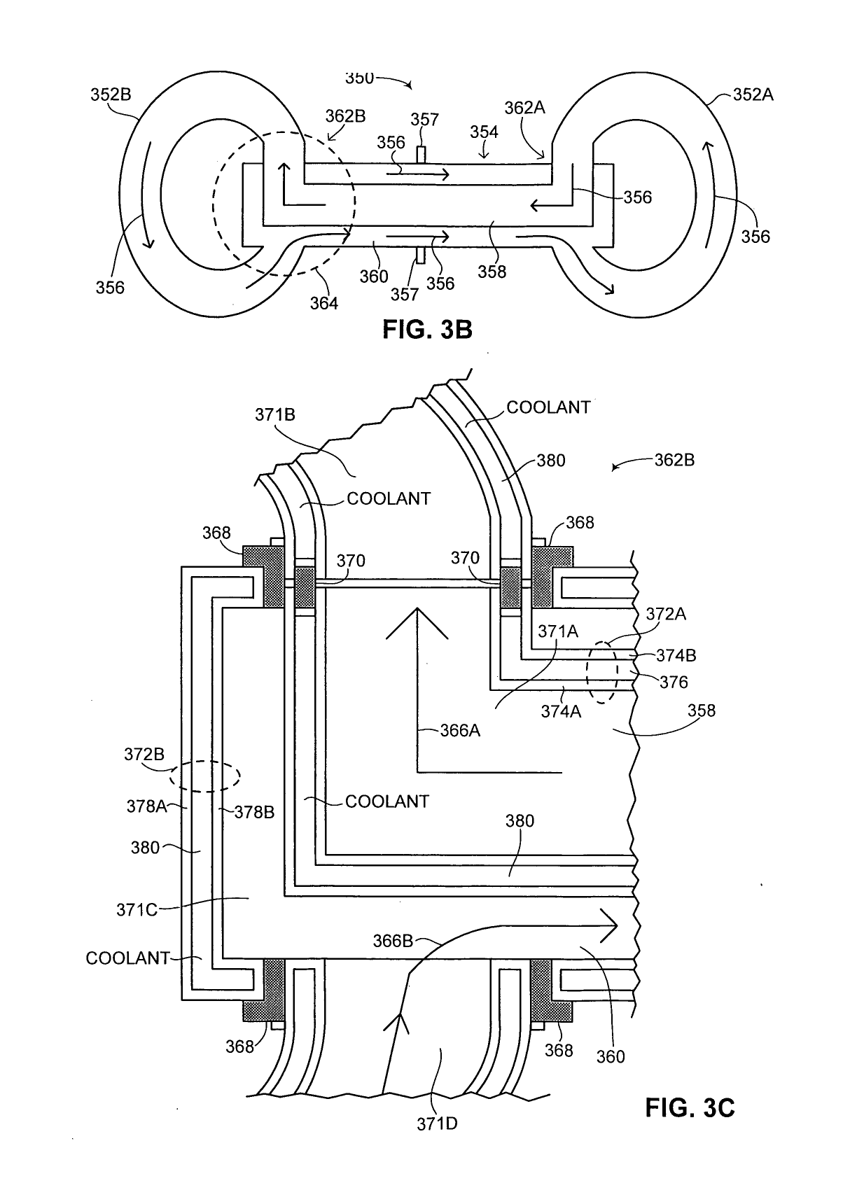

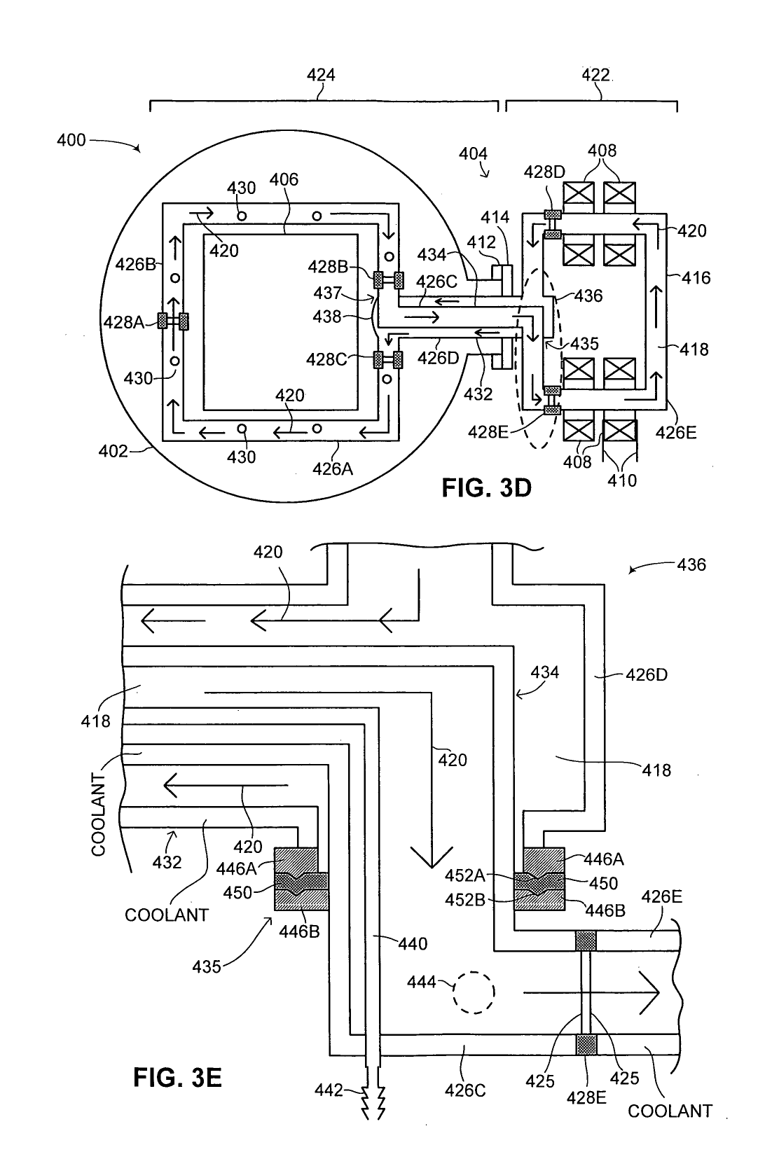

Reference is now made to FIG. 3A, which is a schematic illustration of a single port side-entry interpenetrating circular loop plasma generating system, shown in a top orthogonal view, generally referenced 300, constructed and operative in accordance with a further embodiment of the disclosed. Single port side-entry interpenetrating circular loop plasma generating system 300 (herein referred to as interpenetrating circular plasma generating system 300) includes a PCh 302, a transformer-type plasmatron 304 and a target 306. PCh 302 is maintained at high vacuum conditions, whereas transformer-type plasmatron 304 is maintained at low vacuum conditions. Interpenetrating circular plasma generating system 300 is substantially similar to rectangular loop plasma generating system 100 (FIGS. 1A and 1B) and includes many of the same elements of rectangular loop plasma generating system 100. In general, the main difference between interpenetrating circular plasma generating system 300 and rectangular loop plasma generating system 100 is the shape of the transformer-type plasmatron inserted into the PCh. In order to better explain the disclosed technique, similar elements between interpenetrating circular plasma generating system 300 and rectangular loop plasma generating system 100 have been omitted, such as a target holder, a target heater, a shutter, a target manipulator, a plurality of Knudsen cell evaporation sources, an electron gun evaporator, a gas inlet leaking valve, a capacitance pressure gauge, a view port, a magnetic ring current gauge and the like.

PCh 302 includes a single entry-port 308. Transformer-type plasmatron 304 includes a connection flange 309, a plurality of high permeability magnetic cores 310, a plurality of conductors 312, a interpenetrating loop DCh 314 (herein referred to as either “interpenetrating loop DCh” or simply “DCh”) and a plasma 315. DCh 314 may also include a plurality of dielectric gaskets (not shown). High permeability magnetic cores 310 are positioned around DCh 314. Plurality of conductors 312 are coupled with each of high permeability magnetic cores 310 (not explicitly shown in FIG. 3A). Plurality of conductors 312 are coupled with an RF power source (not shown) as well as an impedance matching network (not shown). Interpenetrating loop DCh 314 is functionally divided into two sections, an outer section 316 and an inner section 318. Inner section 318 is inserted into PCh 302 via entry-port 308, while outer section 316 remains outside PCh 302. Outer section 316 is where plasma 315 is generated while inner section 318 is where plasma 315 is released into PCh 302. Plasma 315 is located all around DCh 314 as shown by a plurality of arrows 324, thereby forming a closed loop. DCh 314 can include a plurality of electrically isolated sections (not shown), with each electrically isolated section being coupled to an adjacent electrically isolated section via a respective dielectric gasket. The portion of DCh 314 which is inserted into entry-port 308 may be sealed with a Teflon® ring (not shown).

DCh 314 has an interpenetrating circular shape, further described below in FIG. 3B. The interpenetrating circular shape includes a smaller diameter tube 330 inserted into a larger diameter tube 328. Larger diameter tube 328 has a circular section 332 which substantially surrounds target 306. The diameter of circular section 332 is constant until a penetrating area, shown by an arrow 326A, where the diameter of circular section 332 is reduced such that circular section 332 has a diameter substantially similar to smaller diameter tube 330 and is represented in FIG. 3A as a straight smaller diameter tube 334. In this respect, circular section 332 penetrates into large diameter tube 328, shown in FIG. 3A as straight smaller diameter tube 334. Together, straight smaller diameter tube 334 and smaller diameter tube 330 form a square shape of outer section 316 where plasma 315 is generated. As shown in FIG. 3A, at a penetrating area 326B, smaller diameter tube 330 is inserted into larger diameter tube 328. Plurality of magnetic cores 310 are placed around smaller diameter tube 330 in outer section 316. Along circular section 332, DCh 314 includes a plurality of apertures 320 for releasing plasma 315 into PCh 302 to be deposited on target 306. As shown in FIG. 3A, each one of plurality of apertures 320 releases plasma 315 into PCh 302 in the form of a respective plume 322. Plurality of apertures 320 substantially resemble plurality of apertures 138 (FIGS. 1A and 1B) and may have sleeves (not shown) inserted into them, wherein the end of each sleeve facing target 306 functions as a nozzle (not shown). Plurality of apertures 320 is substantially evenly positioned around circular section 332 such that plasma 315 released via plurality of apertures 320 will deposit on target 306 substantially uniformly. As compared with closed loop DCh 130 (FIGS. 1A and 1B) and split loop DCh 214 (FIG. 2A), interpenetrating loop DCh 314 may provide a more uniform spread and deposit of plasma 315 on target 306 due to its circular shape and positioning around target 306. Another advantage of interpenetrating loop DCh 314 is that it includes one entry-port 308 instead of two.

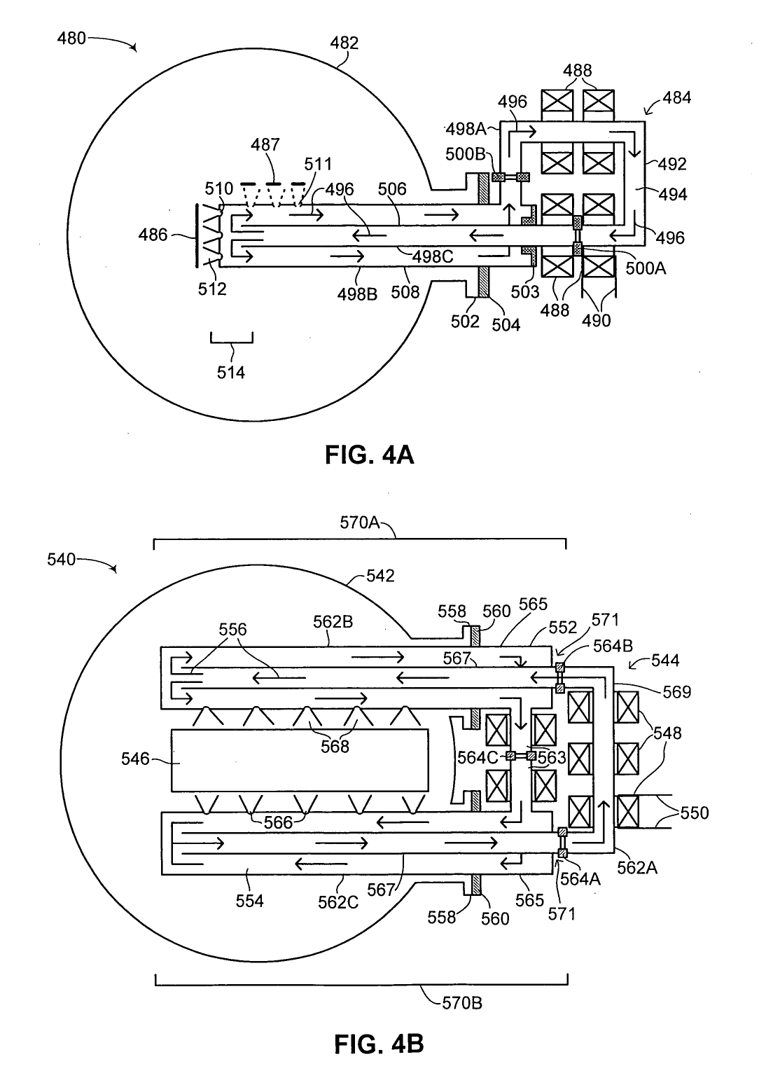

As shown below in FIGS. 3B, 3D, 4A and 4B, the general interpenetrating shape of DCh 314 can be modified to a variety of shapes, thereby accommodating different sizes, shapes and placements of target 306 in PCh 302. For example, circular section 332 may be in the shape of a square (as shown below in FIG. 3D) or rectangle, and smaller diameter tube 330 (i.e., outer section 316) may be in the shape of a circle or a hexagon. Circular section 332 may also be in the shape of a line (as shown below in FIGS. 4A and 4B).

Reference is now made to FIG. 3B, which is a simplified schematic illustration of the interpenetrating loop structure of the single port side-entry interpenetrating circular loop plasma generating system of FIG. 3A, generally referenced 350, constructed and operative in accordance with another embodiment of the disclosed technique. Interpenetrating loop structure 350 includes two loop sections 352A and 352B and an interpenetrating section 354. A plasma (not shown) is substantially present all around the inside of interpenetrating loop structure 350 as shown by a plurality of arrows 356 thereby forming a closed loop. Interpenetrating section 354 includes a smaller diameter tube 358 and a larger diameter tube 360. The plasma is present around loop section 352A and is also present in smaller diameter tube 358. The plasma is present along smaller diameter tube 358 and also in loop section 352B. The plasma is also present in larger diameter tube 360 such that it is in loop section 352A. In a single port side-entry interpenetrating circular loop plasma generating system (not shown) one of loop sections 352A and 352B is located inside a PCh (not shown), whereas the other loop section is located outside the PCh. The loop section located outside the PCh is where a plurality of high permeability magnetic cores (not shown) is placed around that loop section. Interpenetrating section 354 is substantially the section of interpenetrating loop structure 350 which is inserted via a connection flange 357e entry-port into the PCh. Loop sections 352A and 352B enter into interpenetrating section 354 at interpenetrating points 362A and 362B. Interpenetrating point 362B is demarcated by a dotted circle 364 and a magnified view of interpenetrating point 362B is shown in greater detail below in FIG. 3C. Smaller diameter tube 358 is substantially located within larger diameter tube 360. Larger diameter tube 360 substantially surrounds smaller diameter tube 358. The diameter of larger diameter tube 360 is substantially larger than the diameter of smaller diameter tube 358 such that the plasma can freely be present through larger diameter tube 360 from loop section 352B to loop section 352A. The central axis (not shown) of smaller diameter tube 358 must not coincide with the central axis (not shown) of larger diameter tube 360. In general, the central axis of smaller diameter tube 358 is offset in relation to the central axis of larger diameter tube 360. Also, the path of a carrier in both smaller diameter tube 358 and larger diameter tube 360 should be similar. As such, the diameter of larger diameter tube 360 is substantially double the diameter of smaller diameter tube 358. It is noted that smaller diameter and larger diameter tubes 358 and 360 do not have to share the same longitudinal central axis (not shown), although in general the longitudinal central axes of smaller diameter and larger diameter tubes 358 and 360 should be parallel. For example, smaller diameter tube 358 may be placed substantially proximate (not shown in FIG. 3B) to an inner wall (not labeled) of larger diameter tube 360. Such an embodiment would create a large free space (not shown) at the opposite side of the inner wall (not labeled) of larger diameter tube 360, thus enabling a larger mean free path for gas constituents in interpenetrating loop structure 350.

Reference is now made to FIG. 3C, which is a schematic illustration of a close-up of the interpenetrating circular loop structure of FIG. 3B, generally referenced 362B, constructed and operative in accordance with a further embodiment of the disclosed technique. Equivalent elements between FIGS. 3B and 3C are marked using identical numbers. As shown, smaller diameter tube 358 is inserted into larger diameter tube 360. A plasma (not shown) is present throughout smaller diameter tube 358 as shown by an arrow 366A and is present throughout larger diameter tube 360 as shown by an arrow 366B. The interpenetrating circular loop structure of FIG. 3B can substantially be produced from a plurality of different tube sections which are assembled into the interpenetrating circular loop structure of FIG. 3B. For example, as shown in FIG. 3C, smaller diameter tube 358 is produced from a first tube 371A and a second tube 371B, and larger diameter tube 360 is produced from a third tube 371C. A tube section 371D represents the other end of second tube 371B. Each tube may be electrically separated from and simultaneously coupled with an adjacent tube section via a flange coupled with a dielectric gasket. In FIG. 3C, first tube 371A is coupled with second tube 371B via dielectric gaskets 370. Dielectric gaskets 370 couple first tube 371A with second tube 371B while simultaneously electrically separating first tube 371A from second tube 371B. Dielectric gaskets 370 are in the form of a ring. Smaller diameter tube 358 is inserted into larger diameter tube 360, coupled with it and sealed hermetically via seals 368. Seals 368 may be made out of a dielectric material and are in the form of a ring. Seals 368 do not have to hermetically seal larger diameter tube 360 and smaller diameter tube 358. Seals 368 also couple tube section 371D with third tube 371C, while hermetically sealing tube section 371D and third tube 371C. Seals 368 also electrically separate tube section 371D from third tube 371C. It is noted that in another embodiment of the disclosed technique seals 368 are removed (not shown), and smaller diameter tube 358 is welded to larger diameter tube 360. In this embodiment, first tube 371A is welded to third tube 371C such that second tube 371B does not touch third tube 371C. Second tube 371B is thus coupled with first tube 371A via dielectric gaskets 370 yet remains electrically isolated from smaller diameter tube 358.

As shown in FIG. 3C, the double-walled water-cooled construction of smaller diameter tube 358 and larger diameter tube 360 is shown. A dotted ellipse 372A shows the double-walled water-cooled structure of smaller diameter tube 358 and a dotted ellipse 372B shows the double-walled water-cooled structure of larger diameter tube 360. As shown in dotted ellipse 372A, the wall of smaller diameter tube 358 includes a first inner tube 374A and a first outer tube 374B. Between first inner tube 374A and first outer tube 374B, a coolant 376, such as water, is placed. Likewise, as shown in dotted ellipse 372B, the wall of larger diameter tube 360 includes a second inner tube 378B and a second outer tube 378A. First inner tube 374A, first outer tube 374B, second inner tube 378B and second outer tube 378A are each solid walls. The gap (not labeled) between first inner tube 374A and first outer tube 374B is hollow as is the gap (not labeled) between second inner tube 378B and second outer tube 378A. In the gap between second inner tube 378B and second outer tube 378A, a coolant 380, such as water, is placed. Each of first inner tube 374A, second inner tube 378B, first outer tube 374B and second outer tube 378A are made of stainless steel. The walls of smaller diameter tube 358 and larger diameter tube 360 may also include additional tubes (not shown) for introducing and removing coolants 376 and 380 from a single port side-entry interpenetrating circular loop plasma generating system (not shown) of which smaller diameter tube 358 and larger diameter tube 360 form a part of.

Reference is now made to FIG. 3D, which is a schematic illustration of a single port side-entry interpenetrating square loop plasma generating system, shown in a top orthogonal view, generally referenced 400, constructed and operative in accordance with another embodiment of the disclosed technique. Single port side-entry interpenetrating square loop plasma generating system 400 (herein referred to as interpenetrating square plasma generating system 400) includes a PCh 402, a transformer-type plasmatron 404 and a target 406. PCh 402 is maintained at high vacuum conditions, whereas transformer-type plasmatron 404 is maintained at low vacuum conditions. Interpenetrating square plasma generating system 400 is substantially similar to the plasma generating systems described above, in particular to interpenetrating circular plasma generating system 300 (FIG. 3A) and includes many of the same elements of those plasma generating systems. In general, the main difference between interpenetrating square plasma generating system 400 and interpenetrating circular plasma generating system 300 is the shape of the transformer-type plasmatron inserted into the PCh. In order to better explain the disclosed technique, similar elements between interpenetrating square plasma generating system 400 and the plasma generating systems already described have been omitted, such as a target holder, a target heater, a shutter, a target manipulator, a plurality of Knudsen cell evaporation sources, an electron gun evaporator, a gas inlet leaking valve, a capacitance pressure gauge, a view port, a transformer ring core and the like.

PCh 402 includes a single entry-port 412. Transformer-type plasmatron 404 includes a plurality of high permeability magnetic cores 408, a plurality of conductors 410, a connection flange 414, an interpenetrating loop DCh 416 (herein referred to as either “interpenetrating loop DCh” or simply “DCh”) and a plasma 418. Plasma 418 is present throughout the inside of DCh 416 as shown by a plurality of arrows 420. DCh 416 also includes a plurality of dielectric gaskets 428A, 428B, 428C, 428D and 428E. High permeability magnetic cores 408 are positioned around DCh 416. Plurality of conductors 410 are coupled with each of high permeability magnetic cores 408 (not explicitly shown in FIG. 3D). Plurality of conductors 410 are coupled with an RF power source (not shown) as well as an impedance matching network. Interpenetrating loop DCh 416 is functionally divided into two sections, an outer section 422 and an inner section 424. Inner section 424 is inserted into PCh 402 via entry-port 412, while outer section 422 remains outside PCh 402. Outer section 422 is where plasma 418 is generated while inner section 424 is where plasma 418 is released into PCh 402. DCh 416 includes a plurality of electrically isolated sections 426A, 426B, 426C, 426D and 426E. Each one of electrically isolated sections 426A-426E is coupled to an adjacent electrically isolated section via a respective one of dielectric gaskets 428A-428E. The portion of DCh 416 which is inserted into entry-port 412 is sealed using connection flange 414, which may be a standard high vacuum CF 100 flange having a copper gasket (not shown). A dielectric gasket (not shown) may be placed between flange 414 and entry-port 412. The copper gasket may be grounded with PCh 402. Connection flange 414 may also be coupled with a Teflon® gasket (not shown), for electrically separating electrically isolated sections 426C and 426D from entry-port 412. Dielectric gaskets 428A, 428B and 428C are described below with reference to FIG. 7A and dielectric gaskets 428D and 428E are described below with reference to FIG. 7B.

DCh 416 has an interpenetrating square shape, further described below in FIG. 3E. A portion of the interpenetrating square shape is shown in FIG. 3D by a dotted ellipse 436. The interpenetrating square shape includes a smaller diameter tube 434 inserted into a larger diameter tube 432. Larger diameter tube 432 has a partition section 438 into which smaller diameter tube 434 is inserted into. Larger diameter tube 432 has a square section (not labeled) which substantially surrounds target 406, as shown in inner section 424. As shown in FIG. 3D, at partition section 438, smaller diameter tube 434 is inserted into larger diameter tube 432. Plurality of magnetic cores 408 are placed around smaller diameter tube 434 in outer section 422, substantially around electrically isolated section 426E. The diameter of larger diameter tube 432 is about double the diameter of smaller diameter tube 434 so that the mean free path distance of plasma 418 in larger diameter tube 432 is substantially similar to the mean free path distance of plasma 418 in smaller diameter tube 434. Such an embodiment is possible if smaller diameter tube 434 is off-centered in relation to larger diameter tube 432, for example, when both ends of electrically isolated section 426C enter and exit electrically isolated section 426D from the same side (not shown in FIG. 3D). FIG. 3D shows electrically isolated section 426C entering and exiting electrically isolated section 426D from opposite sides.

It is noted that each of electrically isolated sections 426A-426E is made from double-walled water-cooled stainless steel tubing, as described above in FIG. 3C. In general, electrically isolated sections 426A-426D are cooled by a coolant, such as water, which passes in between the double walls of the tubing which electrically isolated sections 426A-426D are made from. For electrically isolated section 426D, coolant is introduced in between its double walls via a first inlet pipe (not shown) coupled with electrically isolated section 426D adjacent to dielectric gasket 428D. The coolant travels between the double walls and exits electrically isolated section 426D (as a hot coolant) at partition section 438 via a first outlet pipe (not shown). The first outlet pipe may be a stainless steel pipe having a diameter of 6 mm. The first outlet pipe is coupled with the inner wall (not labeled) of electrically isolated section 426D and substantially exits electrically isolated section 426D outside PCh 402 adjacent to flange 414. The first outlet pipe does not come in contact with electrically isolated section 426C. Once first outlet pipe exits electrically isolated section 426D, it may be coupled with plastic tubing. For electrically isolated section 426C, coolant is introduced in between its double walls via a second inlet pipe (not shown) coupled with electrically isolated section 426C adjacent to the joint coupling electrically isolated section 426C with electrically isolated section 426D outside PCh 402, labeled by an arrow 435. The coolant travels between the double walls and exits electrically isolated section 426C (as a hot coolant) via a second outlet pipe (not shown) coupled adjacent to the joint coupling electrically isolated section 426C with electrically isolated section 426D inside PCh 402, labeled by an arrow 437. Second outlet pipe may similarly be a stainless steel pipe having a diameter of 6 mm. The second outlet pipe is coupled with the inner wall (not labeled) of electrically isolated section 426C and substantially exits electrically isolated section 426C outside PCh 402 adjacent to joint 435. Once second outlet pipe exits electrically isolated section 426C, it may be coupled with plastic tubing. This is shown in greater detail below in FIG. 3E. It is noted that the second outlet pipe must be at the same potential across electrically isolated section 426C.

For electrically isolated sections 426A and 426B, inlet and outlet pipes (not shown) are respectively introduced in between and exited from the double walls of those electrically isolated sections via dielectric feed-thrus (not shown) which enter through the walls of PCh 402. Dielectric feed-thrus are required in order to maintain the self-potential of electrically isolated sections 426A and 426B. These inlet and outlet pipes can be used as mechanical supports for larger diameter tube 432 inside PCh 402. Outside PCh 402, these inlet and outlet pipes may be coupled with plastic tubing. Coolant is introduced in between the double walls of electrically isolated section 426B via a third inlet pipe (not shown) coupled with electrically isolated section 426B adjacent to dielectric gasket 428B. The coolant travels between the double walls and exits electrically isolated section 426B (as a hot coolant) adjacent to dielectric gasket 428A via a third outlet pipe (not shown). The third outlet pipe may similarly be a stainless steel pipe having a diameter of 6 mm. Coolant is introduced in between the double walls of electrically isolated section 426A via a fourth inlet pipe (not shown) coupled with electrically isolated section 426A adjacent to dielectric gasket 428C. The coolant travels between the double walls and exits electrically isolated section 426A (as a hot coolant) adjacent to dielectric gasket 428A via a fourth outlet pipe (not shown). The fourth outlet pipe may similarly be a stainless steel pipe having a diameter of 6 mm. It is noted in general that coolant is introduced in between the double walls of an electrically isolated section at the lowest point of the tube of that section and exited from the highest point of the tube of that section while minimizing the quantity of air bubbles formed in the coolant.

Flange 414 is coupled with larger diameter tube 432 thereby hermetically sealing transformer-type plasmatron 404 with PCh 402 via entry-port 412. Flange 414 may be electrically grounded with PCh 402, thereby enabling entry-port 412 and flange 414 to be sealed with a standard copper gasket. As an example of the dimensions of entry-port 412, flange 414 and larger diameter tube 432, if entry-port 412 has a diameter of approximately 100 mm, then larger diameter tube 432 may have a diameter approximately between 80-90 mm such that it is easily inserted into entry-port 412. At such dimensions, flange 414 can be embodied as a standard CF 100 flange, as is known in the art. The distance between the end of smaller diameter tube 434 inside PCh 402 and partition section 438 may be approximately 20 mm. Dielectric gaskets 428B and 428E and dielectric gaskets 428C and 428D electrically separate electrically isolated sections 426C and 426D.

In inner section 424, DCh 416 includes a plurality of apertures 430 for releasing plasma 418 into PCh 402 to be deposited on target 406. Each one of plurality of apertures 430 releases plasma 418 into PCh 402 in the form of a respective plume (not shown). Plurality of apertures 430 substantially resemble plurality of apertures 138 (FIGS. 1A and 1B) and may have sleeves (not shown) inserted into them, wherein the end of each sleeve facing target 406 functions as a nozzle (not shown). Plurality of apertures 430 is substantially evenly positioned around the square section such that plasma 418 released via plurality of apertures 430 will deposit on target 406 substantially uniformly. Larger diameter tube 432 and smaller diameter tube 434 may be parallel to target 406. Larger diameter tube 432 and smaller diameter tube 434 may be also be at any angle relative to target 406, including being perpendicular to target 406. In general, target 406 in FIG. 3D does not have a length or width larger than approximately 125 mm in order to ensure that plasma 418 deposits homogeneously on target 406. The dimensions of interpenetrating square plasma generating system 400 may be increased to accommodate a target having a length or width larger than 125 mm provided that additional measures are taken to homogenize the deposition of plasma 418 on the target.

As compared with closed loop DCh 130 (FIGS. 1A and 1B), interpenetrating loop DCh 416 may provide a more uniform spread and deposit of plasma 418 on target 406 due to its square shape and positioning around target 406. It is also noted that both interpenetrating loop DCh 314 (FIG. 3A) and interpenetrating loop DCh 416 respectively simplify the entry and exit of transformer-type plasmatrons 304 (FIG. 3A) and 404 into PCh 302 (FIG. 3A) and PCh 402 respectively, due to their interpenetrating shape and structure, which requires only a single entry-port into the PCh. It is noted, as mentioned above, that both inner section 424 and outer section 422 can have a variety of shapes according to the disclosed technique. For example, outer section 422 may have a circular or elliptical shape. In addition, inner section 424 and outer section 422 may be placed at a variety of angles relative to one another, according to the disclosed technique. For example, outer section 422 and inner section 424 may be placed at right angles relative to one another. The specific shape, form and angular position of outer section 422 relative to inner section 424 is a matter of design choice and is obvious to one skilled in the art.

Reference is now made to FIG. 3E, which is a schematic illustration of a close-up of the interpenetrating square loop structure of FIG. 3D, generally referenced 436, constructed and operative in accordance with a further embodiment of the disclosed technique. Equivalent elements in FIGS. 3D and 3E are labeled using identical numbers. In particular, FIG. 3E shows a close-up of the joint coupling electrically isolated section 426C with electrically isolated section 426D outside PCh 402, labeled by arrow 435. As shown in FIG. 3E, plasma 418 is present inside larger diameter tube 432 and smaller diameter tube 434 as shown by a plurality of arrows 420. Smaller diameter tube 434 has a diameter which is substantially the same as the maximal distance between the outer wall of smaller diameter tube 434 and the inner wall of larger diameter tube 432. Also, smaller diameter tube 434 and larger diameter tube 432 do not necessarily share the same central axis. As shown, dielectric gasket 428E couples electrically isolated section 426C with electrically isolated section 426E while simultaneously electrically separating these sections. Dielectric gasket 428E is in the shape of a ring. Tube ends 425 of smaller diameter tube 434 are also shown in FIG. 3E. FIG. 3E shows an inlet pipe 444, for introducing coolant into the double walls (not shown) of smaller diameter tube 434. Inlet pipe 444 has substantially the same voltage as the voltage across smaller diameter tube 434. Inlet pipe 444 enters the double walls of smaller diameter tube 434. Inlet pipe 444 may be, for example, a 6 mm stainless steel pipe. FIG. 3E also shows an oulet pipe 440 for removing hot coolant from the other end (not shown) of smaller diameter tube 434. Outlet pipe 440 is placed adjacent to the inner wall (not labeled) of smaller diameter tube 434. Outlet pipe 440 may be attached to an exit pipe 442. Outlet pipe 440 is usually made from stainless steel whereas exit pipe 442 may be made from plastic.

FIG. 3E also shows that electrically isolated section 426C is coupled with electrically isolated section 426D such that the two sections are hermetically sealed yet remain electrically isolated. Larger diameter tube 432 includes a circular flange 446A which is coupled with it. Smaller diameter tube 434 includes a circular flange 446B which is coupled with it. Circular flange 446A includes a screw hole (not shown) and a tenon tooth 452A. Circular flange 446B includes a screw hole (not shown) and a mortise 452B. Tenon tooth 452A and mortise 452B each have a substantially annular shape. Mortise 452B is substantially similar in shape to tenon tooth 452A. Circular flange 446A is coupled with circular flange 446B using screws or bolts (not shown) which are inserted into the respective screw holes of circular flanges 446B and 446A. A Teflon® gasket 450 is placed between circular flanges 446A and 446B such that tenon tooth 452A and mortise 452B grip Teflon® gasket 450. Teflon® gasket 450 may be in the form of a ring. The screws are tightened to compress Teflon® gasket 450 between circular flanges 446A and 446B, thereby coupling and hermetically sealing smaller diameter tube 434 with larger diameter tube 432. Dielectric epoxy bushings (not shown), each having a cut-off electrical contact, are positioned at the screw holes for electrically separating larger diameter tube 432 from smaller diameter tube 434.

Reference is now made to FIG. 4A, which is a schematic illustration of a single port side-entry interpenetrating shaft plasma generating system, shown in a top orthogonal view, generally referenced 480, constructed and operative in accordance with another embodiment of the disclosed technique. Single port side-entry interpenetrating shaft plasma generating system 480 (herein referred to as interpenetrating shaft plasma generating system 480) includes a PCh 482, a transformer-type plasmatron 484 and a target 486. PCh 482 is maintained at high vacuum conditions, whereas transformer-type plasmatron 484 is maintained at low vacuum conditions. Interpenetrating shaft plasma generating system 480 is substantially similar to the plasma generating systems described above and includes many of the same elements of those plasma generating systems. In general, the main difference between interpenetrating shaft plasma generating system 480 and the plasma generating systems described above is the shape of the transformer-type plasmatron inserted into the PCh. In order to better explain the disclosed technique, similar elements between interpenetrating shaft plasma generating system 480 and the plasma generating systems already described have been omitted, such as a target holder, a target heater, a shutter, a target manipulator, a plurality of Knudsen cell evaporation sources, an electron gun evaporator, a gas inlet leaking valve, a capacitance pressure gauge, a view port, a magnetic ring current gauge and the like. It is noted that target 486 is substantially similar to target 108 except that target 486 is positioned perpendicularly in PCh 482 to the lengthwise axis (not shown) of transformer-type plasmatron 484. As described below, the target in PCh 482 can also be placed parallel to the lengthwise axis of transformer-type plasmatron 484. This is shown as a target 487, which is denoted by a dotted line. In general, only one target is present in PCh 482, either target 486 or target 487.

PCh 482 includes a single entry-port 502. Transformer-type plasmatron 484 includes a plurality of high permeability magnetic cores 488, a plurality of conductors 490, an interpenetrating shaft DCh 492 (herein referred to as either “interpenetrating shaft DCh” or simply “DCh”) and a plasma 494. Plasma 494 is present inside DCh 492 and forms a closed loop, as shown by a plurality of arrows 496. DCh 492 also includes a plurality of dielectric gaskets 500A and 500B, a Teflon® gasket 503 and a flange 504. High permeability magnetic cores 488 are positioned around DCh 492. Plurality of conductors 490 are coupled with each of high permeability magnetic cores 488 (not explicitly shown in FIG. 4A). Plurality of conductors 490 are coupled with an RF power source (not shown). Interpenetrating shaft DCh 492 is functionally divided into two sections, an outer section (not shown) and an inner section (not shown). The inner section is inserted into PCh 482 via entry-port 502, while the outer section remains outside PCh 482. The outer section is where plasma 494 is generated while the inner section is where plasma 494 is released into PCh 482. DCh 492 includes a plurality of electrically isolated sections 498A, 498B and 498C. Electrically isolated sections 498A, 498B and 498C are coupled with one another via dielectric gaskets 500A and 500B and Teflon® gasket 503. The portion of DCh 492 which is inserted into entry-port 502 is sealed using flange 504, which may be made out of stainless steel. Flange 504 has a substantially annular shape. Dielectric gaskets 500A and 500B are described below with reference to FIG. 7B. As PCh 482 and DCh 492 are only coupled via entry-port 502, no electrical cut-off is needed since this is the only connection between the chambers. Thus a standard high vacuum gasket (not shown) can be placed between entry-port 502 and flange 504. Entry-port 522-502 can be a standard high vacuum CF 100 flange made from stainless steel.

DCh 492 has an interpenetrating shaft shape, substantially represented by electrically isolated sections 498B and 498C. The interpenetrating shaft shape includes a smaller diameter tube 506 inserted into a larger diameter tube 508. Each of smaller diameter tube 506 and larger diameter tube 508 may include a flange (not shown) between which Teflon® gasket 503 is positioned, simultaneously sealing smaller diameter tube 506 and larger diameter tube 508 while keeping them electrically isolated. Plurality of magnetic cores 488 are placed around smaller diameter tube 506 in the outer section, mostly around electrically isolated section 498A. The diameter of larger diameter tube 508 is about double the diameter of smaller diameter tube 506 if the central axes of the two tubes are parallel yet offset from one another so that the mean free path distance of plasma 494 in larger diameter tube 508 is substantially similar to the mean free path distance of plasma 494 in smaller diameter tube 506. In general, the diameter of smaller diameter tube 506 is substantially similar to the maximal distance between the outer wall of smaller diameter tube 506 and the inner wall of larger diameter tube 508. This can be achieved in various configurations of the two tubes. As mentioned above, each of electrically isolated sections 498A, 498B and 498C is made from double-walled water-cooled stainless steel tubing, as described above in FIG. 3C. It is also noted that smaller diameter tube 506 may include a thin stainless steel pipe (not shown), for example one of 6 mm in diameter, for introducing and removing coolant from smaller diameter tube 506, similar to what was described above in FIG. 3E. The pipe may enter and exit smaller diameter tube 506 adjacent to dielectric gasket 500A. It is noted that such a pipe has to be at the same electrical potential as smaller diameter tube 506. Larger diameter tube 508 may include a thin stainless steel pipe (not shown), for example one of 6 mm in diameter, for introducing and removing coolant from larger diameter tube 508, similar to what was described above in FIG. 3E. The pipe may enter and exit larger diameter tube 508 adjacent to Teflon® gasket 503. It is noted that such a pipe has to be at the same electrical potential as larger diameter tube 508.

Along the shaft section of larger diameter tube 508, DCh 492 includes a plurality of apertures 510 for releasing plasma 494 into PCh 482 to be deposited on target 486. Alternatively, DCh 492 may include a plurality of apertures 511 (shown as dotted lines) for releasing plasma 494 into PCh 482 to be deposited on target 487. Each one of plurality of apertures 510 releases plasma 494 into PCh 482 in the form of a respective plume 512. Plurality of apertures 510 and 511 substantially resemble plurality of apertures 138 (FIGS. 1A and 1B) and may have sleeves (not shown) inserted into them, wherein the end of each sleeve facing target 486 or target 487 functions as a nozzle (not shown). Plasma 494 is present throughout electrically isolated section 498A and is also present in smaller diameter tube 506. As plasma 494 is also located at the opening of smaller diameter tube 506, as shown in a section 514, plasma 494 is also located in larger diameter tube 508 as well as the outer section (i.e., the area outside of PCh 482). As mentioned above, electrically isolated sections 498B and 498C may be parallel to or perpendicular to electrically isolated section 498A. In section 514, the distance from the end of smaller diameter tube 506 to the wall of larger diameter tube 508 where plurality of apertures 510 is located may be approximately 40 mm.

As compared with closed loop DCh 130 (FIGS. 1A and 1B), split loop DCh 214 (FIG. 2A), interpenetrating loop DCh 314 (FIG. 3A) and interpenetrating loop DCh 416 (FIG. 3D), interpenetrating shaft DCh 492 enables a target to be deposited with a plasma which is either parallel or perpendicular to the central axis of interpenetrating shaft DCh 492. In addition, like interpenetrating loop DCh 314 and interpenetrating loop DCh 416, interpenetrating shaft DCh 492 simplifies the entry and exit of transformer-type plasmatron 484 into PCh 482, due to the length of its interpenetrating shape, which requires only a single entry-port into the PCh. Another advantage of interpenetrating shaft DCh 492 over previously described DChs is that plasma constituents released into PCh 482 may be free of accompanying parasitic magnetic fields due to the shape and position of smaller diameter tube 506 and larger diameter tube 508. Parasitic magnetic fields may accompany the plasma released via the plurality of apertures from the DCh to the PCh due to a varying electric field inside the inner section of the DCh. The varying electric field may be the result of magnetic induction inside the DCh. In DCh 492, due to the structure of the discharge chamber, the magnetic induction in larger diameter tube 508 substantially cancels any magnetic induction induced in smaller diameter tube 506, thereby leaving no residual magnetic field detected inside PCh 482. Furthermore, the dimensions of interpenetrating shaft plasma generating system 480 may be increased to accommodate a target having a length or width larger than 125 mm provided that additional measures are taken to homogenize the deposition of plasma 494 on the target. For example, entry-port 502 may include a bellows (not shown) for rotating and rocking interpenetrating shaft plasma generating system 480 to homogenize the deposition of plasma 494 on the target. As another example, interpenetrating shaft plasma generating system 480 may be harmonically oscillated around the axis of larger diameter tube 508 to homogenize the deposition of plasma 494 on the target.

Reference is now made to FIG. 4B, which is a schematic illustration of a double port side-entry interpenetrating double shaft plasma generating system, shown in a top orthogonal view, generally referenced 540, constructed and operative in accordance with a further embodiment of the disclosed technique. Double port side-entry interpenetrating double shaft plasma generating system 540 (herein referred to as interpenetrating double shaft plasma generating system 540) includes a PCh 542, a transformer-type plasmatron 544 and a target 546. Interpenetrating double shaft plasma generating system 540 is substantially similar to interpenetrating shaft plasma generating system 480 (FIG. 4A), except that transformer-type plasmatron 544 has two interpenetrating shaft sections, denoted by sections 570A and 570B, which enter into PCh 542 via two entry-ports. All other elements and conditions in interpenetrating double shaft plasma generating system 540 are substantially the same as in interpenetrating shaft plasma generating system 480. In order to better explain the disclosed technique, similar elements between interpenetrating double shaft plasma generating system 540 and the plasma generating systems already described have been omitted.

PCh 542 includes two entry-ports 558. Transformer-type plasmatron 544 includes a plurality of high permeability magnetic cores 548, a plurality of conductors 550, an interpenetrating shaft DCh 552 (herein referred to as either “interpenetrating shaft DCh” or simply “DCh”) and a plasma 554. Plasma 554 is present inside DCh 552 and forms a closed loop, as shown by a plurality of arrows 556. DCh 552 also includes two flanges 560 and a plurality of dielectric gaskets 564A, 564B and 564C. DCh 552 includes a plurality of larger diameter tubes 565, a plurality of smaller diameter tubes 567, a plurality of first connecting tubes 563 and a second connecting tube 569. High permeability magnetic cores 548 are positioned around DCh 552 and are coupled with plurality of conductors 550. The placement of high permeability magnetic cores 548 around plurality of first connecting tubes 563 facilitates the generation of plasma 554 around the relatively long closed loop formed in DCh 552 (as compared to previous embodiments of the disclosed technique described above), as shown by arrows 556. Interpenetrating shaft DCh 552 is functionally divided into two sections, an outer section (not shown) and an inner section (not shown). The inner section is inserted into PCh 542 via two entry-ports 558, while the outer section remains outside PCh 542. The inner section includes plurality of larger diameter tubes 565 and plurality of smaller diameter tubes 567. The outer section includes plurality of first connecting tubes 563 and second connecting tube 569. DCh 552 includes a plurality of electrically isolated sections 562A, 562B and 562C. Electrically isolated sections 562A-562C are coupled with one another via respective ones of dielectric gaskets 564A-564C. The portions of DCh 552 which are inserted into two entry-ports 558 are sealed using flanges 560, which may be made out of stainless steel. Unlike interpenetrating shaft plasma generating system 480 (FIG. 4A), one of the shafts of interpenetrating double shaft plasma generating system 540 must be electrically cut-off from PCh 542. This can be executed by using a Teflon® gasket (not shown) and epoxy bushings (not shown) which are placed in screw holes (not shown) of one of entry-ports 558 used to couple entry-ports 558 with flanges 560. Dielectric gaskets 564A-564C are described below with reference to FIG. 7B. Plurality of first connecting tubes 563 are respectively welded to plurality of larger diameter tubes 565. First connecting tubes 563 are coupled via dielectric gasket 564C. Smaller diameter tubes 567 are coupled with second connecting tube 569 via dielectric gaskets 564A and 564B. Dielectric gaskets (not shown) are used to couple the area where plurality of smaller diameter tubes 567 are inserted into plurality of larger diameter tubes 565, as shown by plurality of arrows 571.

DCh 552 has a double interpenetrating shaft shape, substantially represented by electrically isolated sections 562B and 562C. Each interpenetrating shaft shape includes a smaller diameter tube (not numbered) inserted into a larger diameter tube (not numbered), similar to the interpenetrating shaft shape shown in FIG. 4A. The diameter of the larger diameter tube is such that the mean free path distance of plasma constituents in the larger and smaller diameter tubes is substantially similar in both tubes. As mentioned above, each of electrically isolated sections 562A-562C is made from double-walled water-cooled stainless steel tubing, as described above in FIG. 3C. Along the shaft sections of the larger diameter tubes, DCh 552 includes a plurality of apertures 566 for releasing plasma 554 into PCh 542 to be deposited on target 546. Each one of plurality of apertures 566 releases plasma 554 into PCh 542 in the form of a respective plume 568. Plurality of apertures 566 substantially resemble plurality of apertures 138 (FIGS. 1A and 1B) and may have sleeves (not shown) inserted into them, wherein the end of each sleeve facing target 546 functions as a nozzle (not shown). As mentioned above, electrically isolated sections 562A-562C may be parallel to one another or at any angle relative to one another, including being perpendicular to one another.

As compared with the discharge chambers described above, interpenetrating shaft DCh 552 may enable a larger target to be deposited with plasma 554 uniformly due to its double interpenetrating shaft structure. In addition, the double interpenetrating shaft structure may simplify the entry and exit of a double entry transformer-type plasmatron into a PCh, such as DCh 552 through entry-ports 558, as compared to DCh 130 (FIG. 1A) and DCh 214 (FIG. 2A), since the sections of DCh 130 and DCh 214 which are inserted into the PCh must be coupled inside the PCh as well. Also, similar to interpenetrating shaft DCh 492 (FIG. 4A), plasma constituents released from DCh 552 into PCh 542 may be free of parasitic magnetic fields as induced magnetic fields within PCh 542 are eliminated due to the shape of the inner section of DCh 552. Furthermore, DCh 552 may enable an increased homogeneity of plasma 554 being sprayed on target 546 as two parallel shafts equally spray plasma 554 on target 546 without being affected by parasitic magnetic fields.

Reference is now made to FIG. 5A, which is a schematic illustration of a double port top-entry toroidal plasma generating system, shown in a perspective view, generally referenced 600, constructed and operative in accordance with another embodiment of the disclosed technique. Double port top-entry toroidal plasma generating system 600 (herein referred to as toroidal plasma generating system 600) includes a DCh 602, a PCh 604, a plurality of high permeability magnetic cores 616 and a conductor 617. Toroidal plasma generating system 600 is substantially similar to the plasma generating system described above in FIG. 2A except for, in general, the shape of DCh 602 which is inserted into PCh 604. As mentioned above, PCh 604 is a high vacuum processing chamber in which high vacuum conditions are maintained. The space outside of PCh 604, denoted as a space 603 in FIG. 5A, is not restricted to any particular type of vacuum condition and can be at any pressure and temperature. In contrast, DCh 602 is kept in general at low vacuum and low electrical field conditions. DCh 602 includes an outer section 605, where plasma is generated, an inner section 606, where plasma is released onto a target, a plurality of flanges 623A and 623B, a plurality of dielectric gaskets 625A and 625B and a plurality of apertures 610. DCh 602 may also include an inlet valve (not shown) for introducing a gas into outer section 605. Inner section 606 includes a toroidal section 608. Toroidal section 608 is substantially perpendicular to outer section 605. Plurality of apertures 610 is substantially evenly spaced along the inner side of toroidal section 608. PCh 604 includes two entry-ports 622. Each entry-port may be embodied as a flange (not explicitly shown). DCh 602 is substantially a closed loop. Conductor 617 includes two ends 618A and 618B. Plurality of high permeability magnetic cores 616 are coupled to one another and are looped around outer section 605. Conductor 617 is coupled to each of plurality of high permeability magnetic cores 616 (not explicitly shown). Each of ends 618A and 618B of conductor 617 is coupled to an RF power source (not shown). Conductor 617 is substantially looped around plurality of high permeability magnetic cores 616 a plurality of times. Outer section 605 is coupled with inner section 606 via plurality of dielectric gaskets 625A and 625B which electrically isolate the two sections. Plurality of flanges 623A and 623B are coupled with DCh 602. Entry-ports 622 are coupled with plurality of flanges 623A and 623B via a plurality of dielectric gaskets 620A and 620B (shown below in FIG. 5B), thereby coupling DCh 602 to PCh 604. Plurality of dielectric gaskets 620A and 620B substantially couple DCh 602 with PCh 604 while simultaneously electrically separating DCh 602 from PCh 604. Plurality of dielectric gaskets 620A and 620B and 625A and 625B are further described below in FIG. 7B. DCh 602 is inserted into PCh 604 via entry-ports 622 of PCh 604. An element 627 substantially represents the ceiling of PCh 604. In this respect, DCh 602 is inserted into PCh 604 from the top of PCh 604. PCh 604 can be made of stainless steel.

Toroidal plasma generating system 600 may also include standard components used in plasma generating systems, such as a high vacuum pump, a target (shown in FIG. 5B), a target holder (shown in FIG. 5B), a target heater (shown in FIG. 5B), a target shutter, a target manipulator, at least one Knudsen cell evaporation source and an electron gun evaporator (all not shown). In addition, PCh 604 may further include a pressure gauge, a mass spectrometer, a RHEED tool (all not shown), a target transport mechanism, an infrared pyrometer, a film thickness monitor equipped with a deposition controller, an ion source, an ellipsometer and a plurality of gas sources (all not shown). Other components employed in high vacuum technology may also be included in toroidal plasma generating system 600.

Toroidal plasma generating system 600 generates a plasma based on the principles of a transformer plasmatron as described above. Conductor 617 forms the primary loop of the transformer plasmatron whereas the plasma inside DCh 602 forms the secondary loop of the transformer plasmatron. The RF power source supplies electricity to conductor 617. As electricity travels around the portion of conductor 617 looped around plurality of high permeability magnetic cores 616, a dynamic magnetic field is induced in each one of plurality of high permeability magnetic cores 616. The induced dynamic magnetic field in turns induces a voltage in outer section 605. An inlet valve (not shown) in outer section 605 introduces a gas (not shown) into outer section 605. The induced voltage in outer section 605 substantially ignites the introduced gas and forms a plasma. The formed plasma forms a closed loop in DCh 602, as shown by a set of arrows 624. As mentioned above, the plasma formed is a crude plasma substantially including various different plasma constituents. Due to the induced voltage, the formed plasma is present inside DCh 602 forming a closed loop, as shown by set of arrows 624. Plurality of dielectric gaskets 625A and 625B electrically separates outer section 605 from inner section 606, yet enables the formed plasma to be present in both outer section 605 and in inner section 606. Plasma in toroidal section 608 is evenly present in both sides of toroidal section 608, with a first portion of the plasma being present in toroidal section 608 as shown by an arrow 626A and a second portion of the plasma being present in toroidal section 608 as shown an arrow 626B. Provided that toroidal section 608 is substantially perpendicular to the tube (not numbered) of inner section 606 which couples toroidal section 608 with plurality of dielectric gaskets 620A and 620B, a substantially equal amount of plasma will be present in each side of toroidal section 608, as shown by each of arrows 626A and 626B, similar to split loop plasma generating system 200 (FIG. 2A).

As mentioned above, toroidal section 608 includes a plurality of apertures 610 which are evenly spaced apart. Plurality of apertures 610 enables the formed plasma to be emitted, sprayed or deposited into PCh 604. The formed plasma emitted or sprayed into PCh 604 is in the form of a respective plume 612. The relative dimensions of a given plume 612 are shown by a set of lines 614A and 614B. The relative dimensions of plume 612 substantially represent the relative volume in which the formed plasma emitted into PCh 604 can react or interact with a target (not shown) placed in close proximity to toroidal section 608. This is shown more clearly in FIG. 5B. The size of each one of plurality of apertures 610 is substantially small such that a large Knudsen number (Kn) is maintained in PCh 604. Maintaining a large Kn in PCh 604 substantially ensures that high vacuum conditions are maintained in PCh 604.

Reference is now made to FIG. 5B, which is a schematic illustration of the double port top-entry toroidal plasma generating system of FIG. 5A, shown in a side orthogonal view, generally referenced 650, constructed and operative in accordance with a further embodiment of the disclosed technique. In FIG. 5B, additional elements of toroidal plasma generating system 600 (FIG. 5A) are shown, such as a floor 629 of PCh 604, a target 628, a set of target holders 630A and 630B, a target heater 632 and a set of target heater holders 634A and 634B. Plurality of dielectric gaskets 620A and 620B are visible in FIG. 5B. As shown, set of target holders 630A and 630B hold target 628 at its edges, thereby substantially not blocking the path of any one of plume 612 of the plasma released (not shown), shown by set of lines 614A and 614B, from depositing on target 628. Set of target heater holders 634A and 634B hold target heater 632 in place. Target heater 632 heats target 628 from above, as shown by a set of arrows 636. As seen in FIG. 5B, plurality of apertures 610 are positioned and angled around toroidal section 608 such that each respective plume 612 substantially covers a different area of the surface of target 628, thereby increasing the likelihood of a homogeneous spread of the plasma on target 628. Plurality of apertures 610 can also be positioned and angled around toroidal section 608 such that each respective plume 612 slightly overlaps an adjacent respective plume in an area of the surface of target 628. Also, as shown, plurality of dielectric gaskets 620A and 620B are located outside of PCh 604.

It is noted in general that many other possible shapes for the discharge chambers described in the figures above are possible within the scope of the disclosed technique. For example, any of the general shapes of the discharge chambers described above, such as the loop shape of FIG. 1A, the split loop shape of FIG. 2A or the interpenetrating loop or interpenetrating shaft shape of FIGS. 3A, 3D, 4A and 4B, can be combined to form additional shapes for the discharge chamber used in the disclosed technique. In addition, depending on the chemical process to be executed on the target placed inside the processor chamber, the target may or may not be placed within the mean free path distance of the plasma. For example, in chemical processes which require the various types of plasma constituents in a plasma, the target may need to be placed within the mean free path distance of the plasma such that the plasma constituents do not recombine with one another and annihilate before reaching the target. On the other hand, in chemical processes which require only ions, the target may be placed further than the mean free path distance of the plasma.

Reference is now made to FIG. 6, which is a schematic illustration of a plurality of aperture shapes for emitting plasma constituents, generally referenced 680, constructed and operative in accordance with another embodiment of the disclosed technique. FIG. 6 shows plurality of aperture shapes 680 in a cross-sectional view. Plurality of aperture shapes 680 represent the plurality of apertures and sleeves described above, such as plurality of apertures 138 (FIG. 1A). In FIG. 6, six different aperture shapes are described, an aperture shape 682A, an aperture shape 682B, an aperture shape 682C, an aperture shape 682D, an aperture shape 682E and an aperture shape 682F. Each of aperture shapes 682A-682F includes an inner wall 684 of a DCh (not shown), in which a plasma (not shown) is present and a respective sleeve 688A-688F. Within each inner wall 684 is an opening 686. Via opening 686, the plasma present in the DCH is released into a PCh (not shown), in the direction of plurality of arrows 702A-702F. Within each opening 686, a respective one of sleeves 688A, 688B, 688C, 688D, 688E and 688F is positioned. Sleeve 688A in positioned in opening 686 of aperture shape 682A, sleeve 688B in positioned in opening 686 of aperture shape 682B, sleeve 688C in positioned in opening 686 of aperture shape 682C, sleeve 688D in positioned in opening 686 of aperture shape 682D, sleeve 688E in positioned in opening 686 of aperture shape 682E and sleeve 688F in positioned in opening 686 of aperture shape 682F. Each of sleeves 688A-688F has a respective flange (not shown) for coupling each sleeve to the respective inner wall 684 of each DCh.

Each of sleeves 688A-688F has a different shape, enabling the plasma entering the PCh to enter at different angles and plume shapes or plume profiles. Sleeve 688A has a substantially straight shape, as denoted by a left side 690A and a right side 690B of sleeve 688A. As shown, the plasma enters the PCh in a straight direction, having a circular profile, as indicated by plurality of arrows 702A. Sleeve 688B has a substantially inclined shape, as denoted by a left side 692A, which is straight, and a right side 692B, which is inclined, of sleeve 688B. As shown, the plasma enters the PCh in a straight direction as well as in an inclined direction, having an elliptical profile, as indicated by plurality of arrows 702B. Sleeve 688C has a substantially triangular, or conical shape, as denoted by a left side 694A, which is inclined, and a right side 694B, which is also inclined, of sleeve 688C. As shown, the plasma enters the PCh in a plurality of directions, having a triangular, or conical profile, as indicated by plurality of arrows 702C. Sleeve 688D has a substantially parabolic shape, as denoted by a left side 696A, which is parabolic, and a right side 696B, which is also parabolic, of sleeve 688D. As shown, the plasma enters the PCh in a plurality of directions, having a parabolic profile, as indicated by plurality of arrows 702D. Sleeve 688E also has a substantially parabolic shape, as denoted by a left side 698A, which is parabolic, and a right side 698B, which is also parabolic, of sleeve 688E. As shown, the plasma enters the PCh in a plurality of directions, having a parabolic profile, as indicated by plurality of arrows 702E. The parabolic profiles of aperture shapes 682D and 682E differ in only the curvature of each parabolic profile. Sleeve 688F has a substantially hyperbolic shape, as denoted by a left side 700A, which is hyperbolic, and a right side 700B, which is also hyperbolic, of sleeve 688F. As shown, the plasma enters the PCh in a plurality of directions, having a hyperbolic profile, as indicated by plurality of arrows 702F.

Reference is now made to FIG. 7A is a schematic illustration of a dielectric gasket inside a high vacuum chamber, generally referenced 730, constructed and operative in accordance with a further embodiment of the disclosed technique. As shown above in FIGS. 1A, 1B, 2A, 3C, 3D, 3E, 4A, 4B, 5A and 5B, dielectric gaskets are used to couple various tube sections of a discharge chamber of the disclosed technique. The dielectric gaskets also electrically separate, or electrically insulate, each tube section of the discharge chamber from an adjacent tube section of the discharge chamber. As shown above in the various embodiments of the plasma generating system of the disclosed technique, some of the dielectric gaskets used in the disclosed technique may couple tube sections of the DCh in the inner section of the DCh or in the outer section of the DCh. Recall that the inner section of the DCh is located inside the PCh, whereas the outer section of the DCh is located outside the PCh. Due to differences in pressure and other conditions in the inner section as compared with the outer section of the DCh, the dielectric gaskets used in the disclosed technique differ in configuration depending on whether they are used to couple tube sections of the DCh in the inner section of the DCh or the outer section of the DCh. FIG. 7A shows the shape and configuration of a dielectric gasket used to couple tube sections of a DCh inside a PCh, i.e., in the inner section of the DCh. Examples of such dielectric gaskets include dielectric gaskets 148A (FIGS. 1A and 1B), 222A and 222B (both from FIG. 2A) and 428A, 428B and 428C (all from FIG. 3D). FIG. 7B shows the shape and configuration of a dielectric gasket used to couple tube sections of a DCh outside a PCh, i.e., in the outer section of the DCh. Examples of such dielectric gaskets include dielectric gaskets 428D and 428E (both from FIG. 3D), 500A and 500B (both from FIG. 4A) and 625A and 625B (both from FIG. 5A).

FIG. 7A includes a dielectric gasket 732, which couples and electrically separates a first tube section 738 from a second tube section 740. FIG. 7A shows only one side of dielectric gasket 732 in a cross-sectional view. Dielectric gasket 732 has an annular form. Each of first tube section 738 and second tube section 740 is made from double-walled water-cooled stainless steel. As shown in FIG. 7A, a coolant 734 is placed within the double walls (not numbered) of first tube section 738 and second tube section 740. Each of first tube section 738 and second tube section 740 includes a cap 742, for containing coolant 734 within the double walls of first tube section 738 and second tube section 740. Each of first tube section 738 and second tube section 740 also includes a set of lips 736A and 736B for holding dielectric gasket 732 in place. Dielectric gasket 732 electrically separates first tube section 738 from second tube section 740. Dielectric gasket 732 does not have to completely seal the discharge chamber side of first tube section 738 and second tube section 740 (labeled respectively as 741A and 741B) from leaking plasma (not shown) in the DCh to the processing chamber side of first tube section 738 and second tube section 740 (labeled respectively as 743A and 743B), since a substantially small leak of plasma from the DCh to the PCh will not disrupt the high vacuum conditions in the PCh just as apertures in the DCh which release plasma into the PCh do not disrupt the high vacuum conditions in the PCh. For example, a ring (not shown) may surround dielectric gasket 732, thereby partially sealing a gap 748 between set of lips 736A of first tube section 738 from set of lips 736B of second tube section 738. The ring may be made of ceramic or PBN. The processing chamber side of dielectric gasket 732 may get contaminated by the formation of thin films of metal from metal vapor present in the PCh, which are provided to a target (not shown) in the PCh by a Knudsen cell evaporation source (not shown) or an electron gun evaporator (not shown). A dielectric sleeve 744, covered with a protecting layer 746, both having annular forms, may be placed around dielectric gasket 732 to prevent it from contamination. Dielectric sleeve 744 can be made from silica fabric tape, silica or ceramic. Protecting layer 746 is substantially a metallic foil, made from, for example, tantalum, stainless steel or molybdenum. It is noted that dielectric sleeve 744, when made from silica fabric tape, can also be used to firmly couple first tube section 738 with second tube section 740 when these tube sections are placed at an angle to one another (i.e., when these tube sections are not parallel to one another as shown in FIG. 7A).

Reference is now made to FIG. 7B is a schematic illustration of a dielectric gasket outside a high vacuum chamber, generally referenced 760, constructed and operative in accordance with another embodiment of the disclosed technique. As mentioned above, FIG. 7B shows the shape and configuration of a dielectric gasket used outside a PCh. FIG. 7B includes a dielectric gasket 762, which couples and electrically separates a first tube section 772 from a second tube section 774. FIG. 7B shows only one side of dielectric gasket 762 in a cross-sectional view. Dielectric gasket 762 has an annular form. Each of first tube section 772 and second tube section 774 is made from double-walled water-cooled stainless steel. As shown in FIG. 7B, a coolant 764 is placed within the double walls (not numbered) of first tube section 772 and second tube section 774. Each of first tube section 772 and second tube section 774 includes a respective cap 766A and 776B. Cap 766A includes a gripping tooth 768A and cap 766B includes a gripping tooth 768B. Caps 766A and 766B confine coolant 764 within the double walls of first tube section 772 and second tube section 774. Each of caps 766A and 766B also includes a set of lips (not numbered) for holding dielectric gasket 762 in place. Dielectric gasket 762 electrically separates first tube section 772 from second tube section 774.

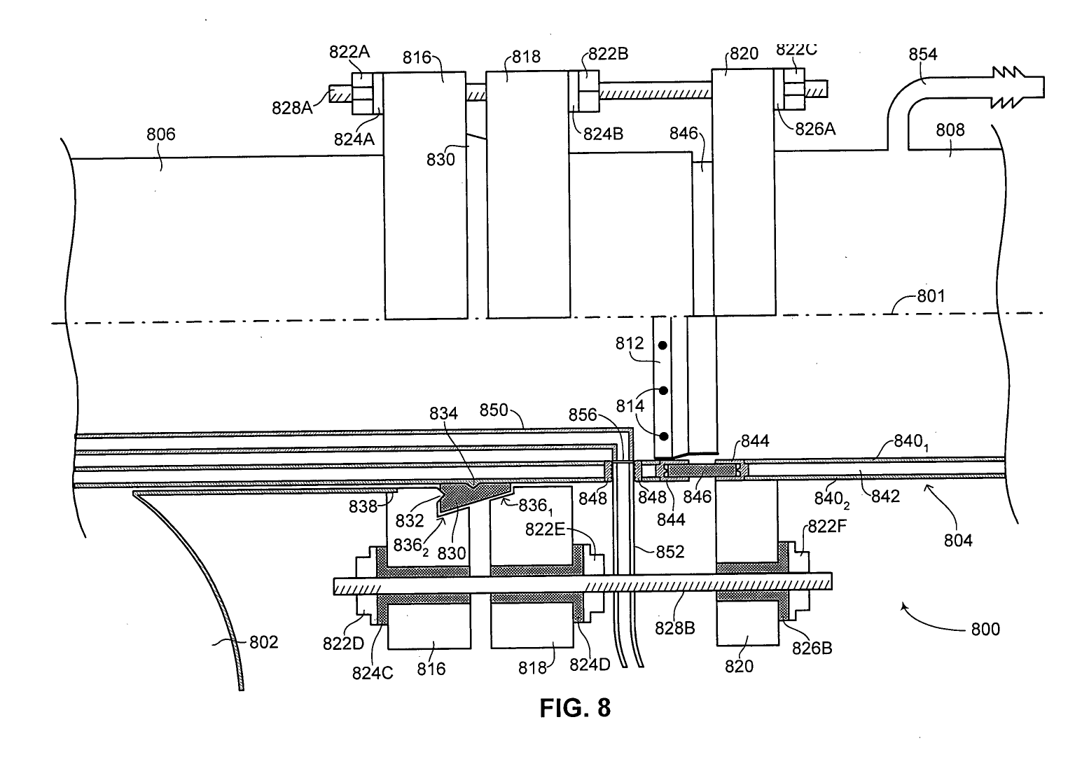

Since dielectric gasket 762 is located outside the PCh, dielectric gasket 762 has to substantially completely seal a gap 776 between caps 766A and 766B of first tube section 772 and second tube section 774 from air in the outside space, which is substantially at atmospheric pressure, which may leak into the discharge chamber via gap 776. To hermetically seal gap 776, dielectric gasket 762 may be made out of Teflon®, which is both dielectric and substantially durable (i.e., Teflon® can undergo substantially deformation before being mechanically disrupted resulting in the disruption of the electrical separation it provides). Caps 766A and 766B may be made out of stainless steel and house dielectric gasket 762. Gripping teeth 768A and 768B grip the ends of dielectric gasket 762 and caps 766A and 766B apply a hydrostatic force on dielectric gasket 762 thereby firmly gripping dielectric gasket 762 and hermetically sealing gap 776. Cap 766A can be gripped against cap 766B via a plurality of methods. For example, each of caps 766A and 766B may have respective flanges (not shown) adjacent to gap 776. A screw (not shown) may be used to compress the two flanges together, thereby compressing gripping teeth 768A and 768B into dielectric gasket 762 and hermetically sealing gap 776. In general, the screw, or any other element or elements used to compress first tube section 772 against second tube section 774 must be isolated by a dielectric material, so that first tube section 772 and second tube section 774 remain electrically separated. In the example just mentioned, the screw compressing the two flanges may be surrounded by a dielectric ring, thereby electrically separating the screw from the two flanges while simultaneously enabling the screw to compress the two flanges together. Another example of a configuration for compressing first tube section 772 with second tube section 774 is shown below in FIG. 8.

Dielectric gasket 762 is used to couple tube sections of the DCh where a plasma of the disclosed technique is ignited and generated. As such, the discharge chamber side of dielectric gasket 762 may get burned from the ignited plasma in the DCh. To protect dielectric gasket 762, which may be made of Teflon®, a shield 770 is placed around gap 776. Shield 770 can be made from stainless steel, tantalum or molybdenum foil. Shield 770 may be coupled with one of caps 766A or 766B, either one of first tube section 772 or second tube section 774 by welding, such as weld joint 778. The welding may be executed by arc welding or laser beam welding.

In order to simplify the assembly and disassembly of the plasma generating systems of the disclosed technique, the plasma generating system of the disclosed technique can be constructed such that a portion of the transformer-type plasmatron of the disclosed technique can be inserted into the high vacuum PCh while another portion of the transformer-type plasmatron of the disclosed technique can be coupled with it from the outside. Such an embodiment enables the DCh of the disclosed technique to be disassembled while maintaining the high vacuum pressure conditions inside the PCh as well as the dielectric separation between the PCh and the DCh. Such an embodiment of the disclosed technique is shown below in FIG. 8.

Reference is now made to FIG. 8, which is a schematic illustration of an entry-port of the plasma generating system of the disclosed technique, shown in a partial cut-away view, generally referenced 800, constructed and operative in accordance with a further embodiment of the disclosed technique. Entry-port 800 substantially shows the entry of a DCh 804 into a PCh 802 as well as the coupling of DCh 804 to PCh 802. Entry-port 800 is substantially similar to entry-ports 122 (FIG. 1A), 208 (FIG. 2A), 308 (FIG. 3A), 412 (FIG. 3D), 502 (FIG. 4A) and 558 (FIG. 4B) and can represent any one of those entry-ports. Entry-port 800 is shown in a partial cut-away view around a center line 801. Above center line 801, an external view of entry-port 800 is shown whereas below center line 801, a cross-sectional view of entry-port 800 is shown. As shown in embodiments of the plasma generating system of the disclosed technique above, such as interpenetrating square plasma generating system 400 (FIG. 3D), the DCh of the disclosed technique includes a number of tube sections. As shown in FIG. 8, DCh 804 includes an inner tube 806 and an outer tube 808. DCh 804 may include additional tubes which are not shown for purposes of clarity. As described below, inner tube 806 is first coupled with PCh 802, with inner tube 806 extending into regular atmospheric pressure conditions. Then outer tube 808 is coupled and sealed together with inner tube 806. Inner tube 806 is coupled with PCh 802 as described below. Each one of inner tube 806 and outer tube 808 is made from double-walled water-cooled stainless steel tubing and may have an outer diameter of approximately 50 millimeters. As shown, for example, outer tube 808 includes an inner wall 840₁ and an outer wall 840₂. Between inner wall 840₁ and outer wall 840₂ a coolant 842 is placed. A cap 844 seals the end of inner wall 840₁ and outer wall 840₂ of outer tube 808 as well as of inner tube 806. Inner tube 806 includes a protrusion 834 on its outer wall. Outer tube 808 includes a second flange 820 which is coupled with an end of outer tube 808. Second flange 820 may be welded to cap 844 and outer wall 840₂.

Inner tube 806 is coupled with outer tube 808 via a dielectric gasket 846. Dielectric gasket 846 is substantially similar to dielectric gasket 762 (FIG. 7B). Dielectric gasket 846 electrically separates inner tube 806 from outer tube 808 while physically coupling them together. Dielectric gasket 846 also hermetically seals DCh 804. A shield 812, similar to a shield 770 (FIG. 7B) is placed around dielectric gasket 846. Shield 812 is coupled with the inner wall of inner tube 806 by a plurality of weld joints 814.

PCh 802 includes a port flange 816 which is coupled with PCh 802 at a section 838. Port flange 816 may be welded to PCh 802 at section 838. Port flange 816 includes a protrusion 832 and has a recess 836₂. In general, the inner diameter of port flange 816 is slightly larger than the outer diameter of inner tube 806. Depending on the dimensions of PCh 802 and inner tube 806, port flange 816 may be a standard high vacuum CF 63 flange. Entry-port 800 is assembled by first inserting inner tube 806 into PCh 802. A gasket ring 830 is then inserted around inner tube 806. Gasket ring 830 can be made from any dielectric material, such as Teflon®. Gasket ring 830 may also be made from a dielectric material which is also robust, such as Teflon®. Gasket ring 830 has a polygonal shaped cross-section. Gasket ring 830 is shaped to substantially match the shape of recess 836₂. A first flange 818 is then inserted around inner tube 806. First flange 818 is a floating flange and is not permanently coupled with inner tube 806. First flange 818 includes a recess 836₁. Gasket ring 830 is also shaped to substantially match the shape of recess 836₁. Port flange 816 and first flange 818 are substantially similar in size and shape, thereby forming a flange and counter-flange pair. Depending on the dimensions of PCh 802 and inner tube 806, port flange 816 and first flange 818 may be embodied as standard flanges. In such an embodiment, first flange may be permanently coupled to inner tube 806 and may not be a floating flange. The type of flanges used in entry-port 800 is a matter of design choice and can depend on various factors such as cost, workability and ease of assembly. As described below, port flange 816 and first flange 818 are compressed together using screws. The compression force of port flange 816 on first flange 818 forces gasket ring 830 into protrusions 832 and 834. The compression force on gasket ring 830 is substantially a hydrostatic force which substantially seals port flange 816 with first flange 818 while keeping them electrically separated. Protrusions 832 and 834 firmly grip gasket ring 830 and couple PCh 802 with inner tube 806. Gasket ring 830 electrically separates PCh 802 from inner tube 806 and also hermetically seals entry-port 800 of PCh 802. It is obvious to a worker skilled in the art that recesses 836₁ and 836₂ and gasket ring 830 can have other shapes and configurations which enable inner tube 806 to be coupled with PCh 802 while simultaneously being hermetically sealed and electrically separated. Dielectric gasket 846 is then coupled with inner tube 806 and outer tube 808 is then coupled with inner tube 806 via dielectric gasket 846. A compression force is exerted on inner tube 806 and outer tube 808 to hermetically seals the tubes together via screws which couple second flange 820 with first flange 818.

Screws 828A and 828B are inserted through screw holes (not labeled) in port flange 816, first flange 818 and second flange 820 which respectively line up with one another. In order to physically couple port flange 816, first flange 818 and second flange 820 while simultaneously keeping port flange 816, first flange 818 and second flange 820 electrically separated, a plurality of dielectric bushings 824A-824D and a plurality of sleeves 826A and 826B are inserted between the screw holes and screws 828A and 828B. Plurality of dielectric bushings 824A-824D and plurality of sleeves 826A and 826B can be made from known dielectric materials, such as an epoxy resin for example. Once plurality of dielectric bushings 824A-824D and plurality of sleeves 826A and 826B are placed in the screw holes, screws 828A and 828B are then inserted and fastened using a plurality of nuts 822A-822F. It is noted that outer tube 808 can be coupled with inner tube 806 and port flange 816 using other configurations which are a matter of design choice. For example, a long band (not shown), instead of second flange 820, could be used to couple outer tube 808 to inner tube 806, by coupling a bend or curve (not shown) in outer tube 808 to inner tube 806. In such an example, appropriate electrical separating adjacent to the bend or curve would be required to insure that inner tube 806 and outer tube 808 remain electrically separated.

Entry-port 800 also shows the introduction and exit of coolant into the double-walled sections of inner tube 806 and outer tube 808. In outer tube 808, a coolant inlet tube 854 is shown, coupled with the outer surface of outer tube 808. Coolant inlet tube 854 may be welded to the outer surface of outer tube 808 and substantially introduces coolant into outer tube 808. In inner tube 806, a coolant outlet tube 850 is shown. As inner tube 806 is substantially placed inside PCh 802, a coolant inlet tube (not shown) is used to introduce coolant into inner tube 806 adjacent to a dielectric gasket (not shown) positioned inside PCh 802, coupling inner tube 806 with another tube (not shown) inside PCh 802. Coolant is then removed from inner tube 806 via coolant outlet tube 850. Coolant outlet tube 850 is positioned along the inner wall of inner tube 806 in order to maintain the self-potential of inner tube 806. Both coolant inlet tube 854 and coolant outlet tube 850 can be made from stainless steel, thus enabling the ends of the tubes to be welded respectively to outer tube 808 and inner tube 806. Each of coolant inlet tube 854 and coolant outlet tube 850 may have a diameter of approximately 6 millimeters.

A stainless steel threaded bushing 848 is positioned inside the double wall of inner tube 806 to enable coolant outlet tube 850 to exit inner tube 806. Stainless steel threaded bushing 848 is welded to the double wall of inner tube 806. Coolant outlet tube 850 is coupled with one end of stainless steel threaded bushing 848, usually by welding, as shown in FIG. 8 as a line 856. An outtake pipe 852 is coupled with another end of stainless steel threaded bushing 848 adjacent to line 856 for removing the coolant. In general, outtake pipe 852 is coupled with inner tube 806 only after port flange 816, first flange 818 and gasket ring 830 have been positioned and coupled together. Outtake pipe 852 can be made from Teflon® or from stainless steel with an appropriate water seal, as is known in the art, such as Teflon® foil.

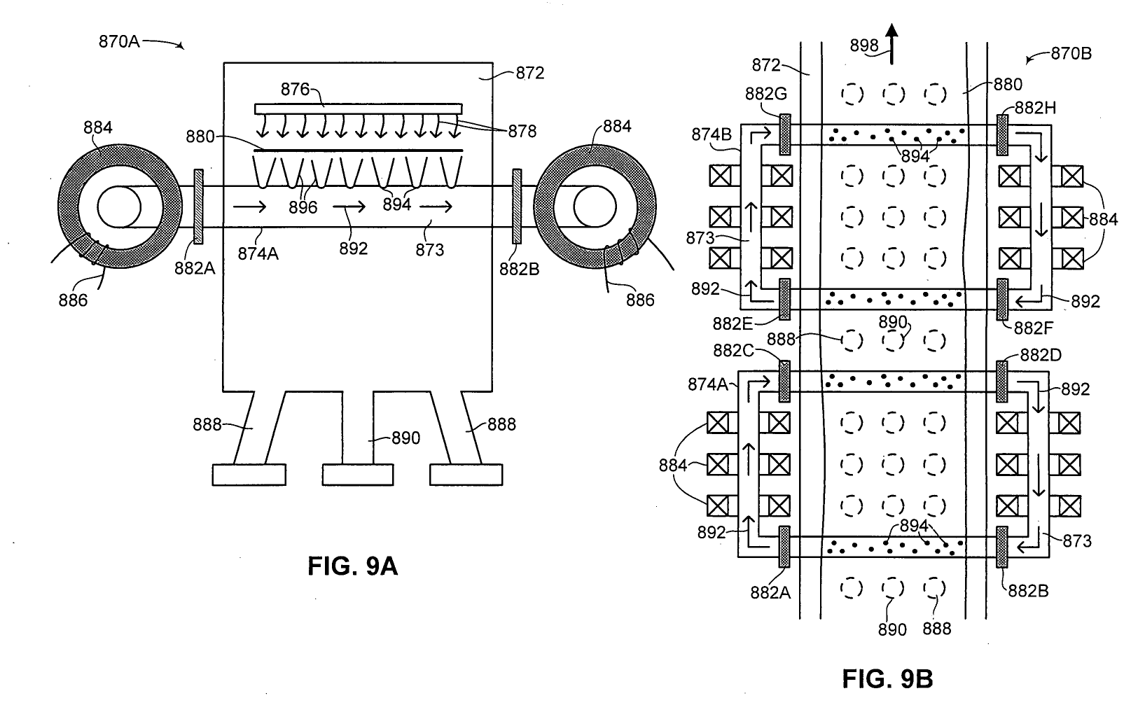

In general, the embodiments of the disclosed technique described (FIGS. 1A-8) have described a plasma generating system for high vacuum batch wafer processing chambers in which relatively small sized targets can be processed. FIGS. 9A-12B describe plasma generating systems for high vacuum roll-to-roll processing chambers in which target rolls can be processed. Such rolls may be substantially large in width and substantially endless in length. The roll-to-roll processing plasma generating systems described below substantially operate on the same principles of plasma generation in transformer-type plasmatrons as described above, except their configuration has been modified to enable significantly larger targets, in the form of rolls, to be processed. As such, only the basic structure of these embodiments is shown for purposes of clarity. In addition, other elements included in transformer-type plasmatrons, as mentioned above, for example in FIG. 1A, have been omitted for purposes of clarity.

Reference is now made to FIGS. 9A and 9B. FIG. 9A is a schematic illustration of a roll-to-roll processing plasma generating system, shown in a side orthogonal view, generally referenced 870A, constructed and operative in accordance with another embodiment of the disclosed technique. FIG. 9B is a schematic illustration of the roll-to-roll processing plasma generating system of FIG. 9A, shown in a top orthogonal view, generally referenced 870B, constructed and operative in accordance with a further embodiment of the disclosed technique. Identical elements in FIGS. 9A and 9B are labeled using identical numbers, although it is noted that not all elements visible in FIG. 9A may be visible in FIG. 9B and vice-versa. As shown in the side orthogonal view of FIG. 9A, roll-to-roll processing plasma generating system 870A includes a PCh 872, a plurality of discharge chambers (herein abbreviated DChs) 874A (only one is shown in FIG. 9A), a target heater 876, a target roll 880, a plurality of dielectric gaskets 882A-882B, a plurality of high permeability magnetic cores 884 (herein referred to as ferrite cores), a plurality of conductors 886, a plurality of Knudsen cell evaporation sources 888 and a plurality of electron gun evaporators 890. Plurality of DChs 874A includes a plurality of apertures 894 for releasing a plasma 873 inside plurality of DChs 874A in the direction of target roll 880.

Plurality of conductors 886 are wound around plurality of ferrites cores 884 and are coupled with respective RF power sources (not shown). As mentioned above, roll-to-roll processing plasma generating system 870A includes other elements described in other embodiments of the disclosed technique, such as a plurality of gas inlet leaking valves (not shown), a plurality of view ports (not shown) and a plurality of magnetic ring current gauges (not shown) and the like. Gas inside plurality of DChs 874A is ignited and forms plasmas 873, which is present throughout plurality of DChs 874A, as shown by a plurality of arrows 892. Plurality of DChs 874A each include a plurality of electrically separated sections (not labeled), which are coupled together yet electrically separated via plurality of dielectric gaskets 882A-882B. Target roll 880 moves in a direction perpendicular to the plane of roll-to-roll processing plasma generating system 870A shown in FIG. 9A. As target roll 880 is moved, target heater 876 may heat target roll 880, as shown by a plurality of arrows 878. Plurality of apertures 894 release plasma 873 in the form of a plurality of plumes 896 towards target roll 880. The distance between plurality of apertures 894 and target roll 880 may be less than the mean free path distance of the plasma constituents in plasma 873. As target roll 880 is moved forward, plasma constituents of plasma 873 deposit on target roll 880. Plurality of DChs 874A may each have a rectangular shape, similar to closed loop DCh 130 (FIGS. 1A and 1B). Plurality of Knudsen cell evaporation sources 888 and plurality of electron gun evaporators 890 may be used to deposit elements, compounds and particles on target roll 880. Plurality of Knudsen cell evaporation sources 888 and plurality of electron gun evaporators 890 may be positioned in the open space of plurality of DChs 874A (shown more clearly in FIG. 9B) and between adjacent ones of plurality of DChs 874A (shown more clearly in FIG. 9B) such that elements, compounds and particles released impinge upon the surface of target roll 880.

FIG. 9B shows roll-to-roll processing plasma generating system 870B from a top view. In FIG. 9B, a plurality of DChs 874A and 874B is visible. It is clear to the worker skilled in the art that more DChs could be present in roll-to-roll processing plasma generating system 870B. As shown each one of plurality of DChs 874A and 874B includes a plurality of ferrites cores 884. Each one of plurality of DChs 874A and 874B includes four electrically separated sections (not labeled) separated by plurality of dielectric gaskets 882A-882H. Plasma 873 is present throughout each of plurality of DChs 874A and 874B as shown by plurality of arrows 892. As shown, sections of plurality of DChs 874A and 874B are located inside PCh 872 and sections of plurality of DChs 874A and 874B are located outside of PCh 872. Target roll 880 moves in a forward direction, as shown by an arrow 898. Target roll 880 is completely located inside PCh 872. As shown in FIG. 9B, plurality of apertures 894 are evenly spaced along the sections of plurality of DChs 874A and 874B that are located inside PCh 872 such that plasma 873 is evenly deposited on target roll 880. Also as seen in FIG. 9B, plurality of Knudsen cell evaporation sources 888 and plurality of electron gun evaporators 890 are placed between adjacent ones of plurality of DChs 874A and 874B as well as in the open spaces formed by the rectangular shape of each one of plurality of DChs 874A and 874B. In general, roll-to-roll processing plasma generating system 870B can be used to deposit a plurality of layers of plasma on a target roll. In addition, since each one of plurality of DChs 874A and 874B has a separate gas inlet leaking valve (not shown), each one of plurality of DChs 874A and 874B can act as a separate station in processing target roll 880 with different types of plasmas and plasma constituents.

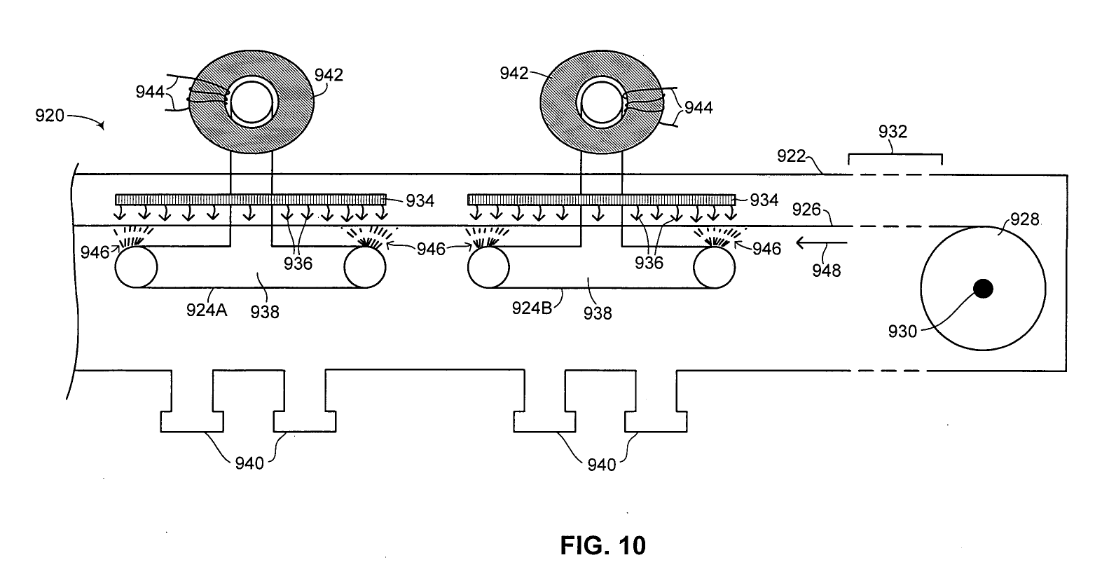

Reference is now made to FIG. 10, which is a schematic illustration of another roll-to-roll processing plasma generating system, shown in a side orthogonal view, generally referenced 920, constructed and operative in accordance with another embodiment of the disclosed technique. Roll-to-roll processing plasma generating system 920 includes a PCh 922, a plurality of DChs 924 and 924B, a target roll 926, a plurality of target heaters 934, a plurality of Knudsen cell evaporation sources 940, a plurality of high permeability magnetic cores 942 and a plurality of conductors 944. Roll-to-roll processing plasma generating system 920 includes other elements as shown above in other embodiments of the disclosed technique, which have been omitted from FIG. 10 for purposes of clarity. A section 932 shows that target roll 926 may be substantially long and that more than two DChs may be present in roll-to-roll processing plasma generating system 920. Target roll 926 is initially wrapped around a cylindrical roller 928 which can rotate about a shaft 930. Another cylindrical roller (not shown) may be placed at the other end of PCh 922 (not shown) for receiving and rolling target roll 926 after it has been processed. Target roll 926 is moved in the direction of an arrow 948. As target roll 926 approaches each one of plurality of DChs 924A and 924B, plurality of target heaters 934 heat up target roll 926, as shown by a plurality of arrows 936. Plurality of high permeability magnetic cores 942 and plurality of conductors 944 ignite gas (not shown) in plurality of DChs 924A and 924B as a plasma 938. A plurality of apertures (not shown) in plurality of DChs 924A and 924B release plasma 938 towards target roll 926, as shown by a plurality of lines 946. Plasma 938 then deposits on target roll 926. Plurality of Knudsen cell evaporation sources 940 are positioned along PCh 922 such that they can release elements and compounds which will impinge upon the surface of target roll 926.

As shown in the embodiment of the disclosed technique in FIGS. 9A and 9B, each one of plurality of DChs 924A and 924B may represent a separate processing station for depositing a plurality of layers of plasma on target roll 926. As shown in FIG. 10, each one of plurality of DChs 924A and 924B has a shape similar to the shape of split loop 250 (FIG. 2B). It is noted that the plurality of DChs shown in FIGS. 9A, 9B and 10 can have shapes resembling the DChs shown in previously described embodiments of the disclosed technique, such as the rectangular loop shape of DCh 130 (FIGS. 1A and 1B) and the split loop shape of DCh 214 (FIG. 2A). It is obvious to a worker skilled in the art that other DCh shapes are possible and are a matter of design choice. In general, the plurality of DChs shown in FIGS. 9A, 9B and 10 can have any closed symmetrical shape enabling the passage of a target roll and being open to enable the deposition of elements and compounds from a plurality of Knudsen cell evaporation sources. In addition, the shape of a given one of plurality of DChs shown in FIGS. 9A, 9B and 10 need not necessarily be the same shape as another given one of plurality of DChs shown in FIGS. 9A, 9B and 10.

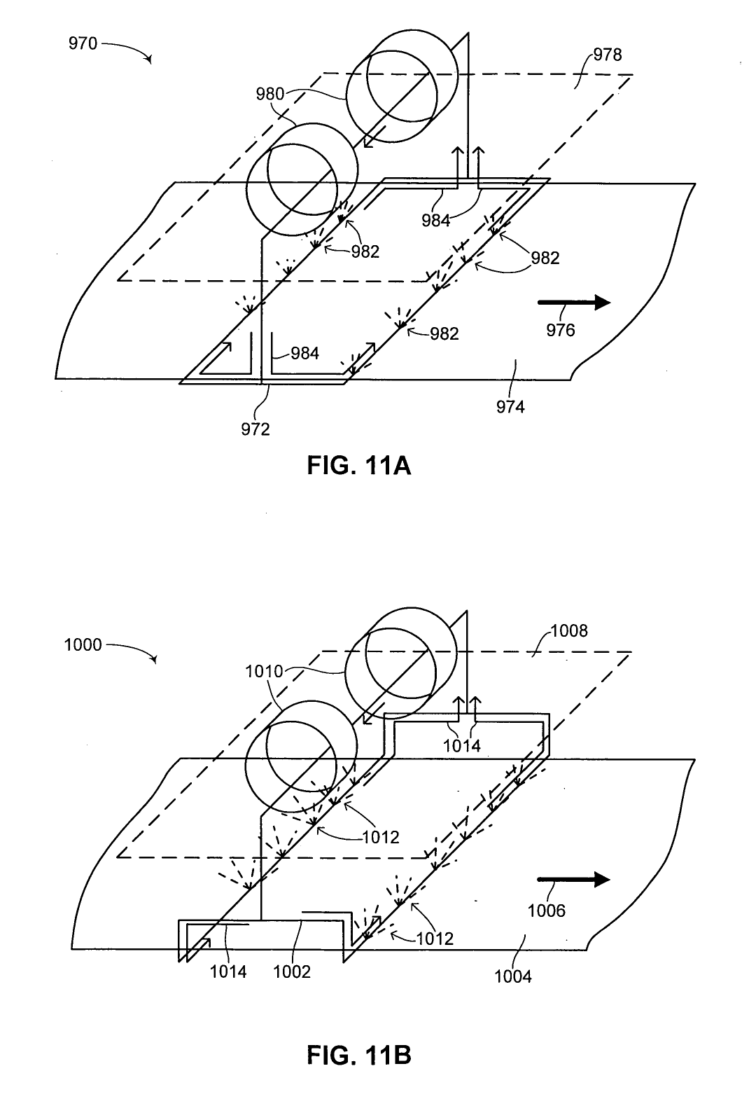

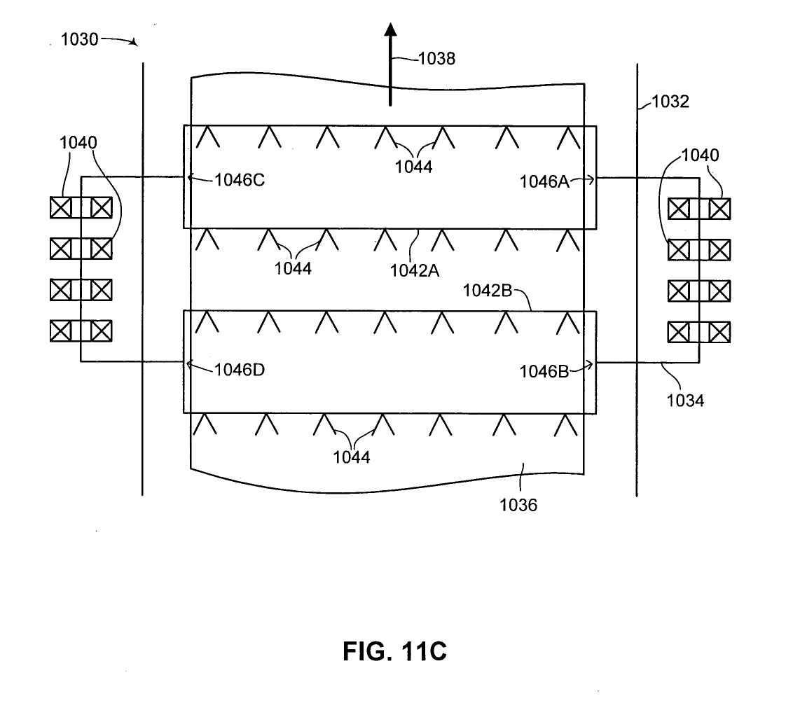

Reference is now made to FIGS. 11A, 11B and 11C which show simplified schematic illustrations of other roll-to-roll processing plasma generating systems. In general, these illustrations have been greatly simplified, with many elements of the disclosed technique omitted, in order to show additional shapes and configurations of DChs which can be used with the disclosed technique. Reference is now made to FIG. 11A, which is a simplified schematic illustration of another roll-to-roll processing plasma generating system, shown in a perspective view, generally referenced 970, constructed and operative in accordance with a further embodiment of the disclosed technique. As mentioned above, FIG. 11A has been greatly simplified with many elements in previous embodiments of the disclosed technique having been omitted for purposes of clarity. Roll-to-roll processing plasma generating system 970 includes a DCh 972, a target roll 974 and a plurality of high permeability magnetic cores 980. A plane 978 represents the ceiling of a PCh (not shown). Elements below plane 978 are in the PCh, whereas elements above plane 978, such as plurality of high permeability magnetic cores 980 are external to the PCh. Target roll 974 moves in a direction of an arrow 976. Plasma is present throughout DCh 972 as shown by a plurality of arrows 984. A plurality of apertures (not shown) in DCh 972 enable the plasma in DCh 972 to be released and evenly deposited on target roll 974, as shown by a plurality of lines 982. As shown DCh 972 has a rectangular shape parallel to target roll 974 and a U-shape perpendicular to target roll 974 which exits and enters the PCh. In general, the shape of DCh 972 is symmetric along a plane (not shown) such that plasma (not labeled) is equally located throughout DCh 972. Plurality of high permeability magnetic cores 980 are placed around DCh 972 outside the PCh. It is obvious to the worker skilled in the art that additional DChs equivalent to DCh 972 could be lined up one after the other along the PCh above target roll 974. Each DCh (not shown) would then represent a processing station in roll-to-roll processing plasma generating system 970.

Reference is now made to FIG. 11B, which is a simplified schematic illustration of a further roll-to-roll processing plasma generating system, shown in a perspective view, generally referenced 1000, constructed and operative in accordance with another embodiment of the disclosed technique. As mentioned above, FIG. 11B has been greatly simplified with many elements in previous embodiments of the disclosed technique having been omitted for purposes of clarity. Roll-to-roll processing plasma generating system 1000 includes a DCh 1002, a target roll 1004 and a plurality of high permeability magnetic cores 1010. A plane 1008 represents the ceiling of a PCh (not shown). Elements below plane 1008 are in the PCh, whereas elements above plane 1008, such as plurality of high permeability magnetic cores 1010 are external to the PCh. Target roll 1004 moves in a direction of an arrow 1006. Plasma is present throughout DCh 1002 as shown by a plurality of arrows 1014. A plurality of apertures (not shown) in DCh 1002 enable the plasma in DCh 1002 to be released and evenly deposited on target roll 1004, as shown by a plurality of lines 1012. As shown DCh 1002 has a generally rectangular shape parallel to target roll 1004 and a U-shape perpendicular to target roll 1004 which exits and enters the PCh. In general, the shape of DCh 1002 is symmetric along a plane (not shown) such that plasma (not labeled) is equally located throughout DCh 1002. The shape of DCh 1002 may simplify assembly of DCh 1002 in the PCh as compared with DCh 972 (FIG. 11A). Plurality of high permeability magnetic cores 1010 are placed around DCh 1002 outside the PCh. It is obvious to the worker skilled in the art that additional DChs equivalent to DCh 1002 could be lined up one after the other along the PCh above target roll 1004. Each DCh (not shown) would then represent a processing station in roll-to-roll processing plasma generating system 1000.

Reference is now made to FIG. 11C, which is a simplified schematic illustration of another roll-to-roll processing plasma generating system, shown in a top orthogonal view, generally referenced 1030, constructed and operative in accordance with a further embodiment of the disclosed technique. As mentioned above, FIG. 11C has been greatly simplified with many elements in previous embodiments of the disclosed technique having been omitted for purposes of clarity. Roll-to-roll processing plasma generating system 1030 includes a PCh 1032, a DCh 1034, a target roll 1036 and a plurality of high permeability magnetic cores 1040. Target roll 1036 moves in a direction of an arrow 1038. A plurality of apertures (not shown) in DCh 1034 enable the plasma in DCh 1034 to be released and evenly deposited on target roll 1036, as shown by a plurality of lines 1044. As shown DCh 1034 branches off into two rectangular shaped DChs 1042A and 1042B at four branch points 1046A, 1046B, 1046C and 1046D. In this embodiment, a single group of high permeability magnetic cores (such as the eight magnetic cores shown in FIG. 11C) can be used to generate a plasma in a plurality of rectangular shaped DChs, thereby increasing cost effectiveness and reducing parts in roll-to-roll processing plasma generating system 1030. In general, the shape of DCh 1034 is symmetric along a plane (not shown) such that plasma (not labeled) is equally located throughout DCh 1034. It is obvious to the worker skilled in the art that additional DChs equivalent to DCh 1034 could be lined up one after the other inside PCh 1032, with each additional DCh (not shown) then representing a processing station in roll-to-roll processing plasma generating system 1030. It is also obvious to the worker skilled in the art that many other variations of DCh 1034 as well as the DChs shown in FIGS. 11A and 11B are possible and are a matter of design choice for evenly releasing plasma onto a processing target roll.

It will be appreciated by persons skilled in the art that the disclosed technique is not limited to what has been particularly shown and described hereinabove. Rather the scope of the disclosed technique is defined only by the claims, which follow.

1. Plasma generating apparatus comprising:
a high vacuum processing chamber;
a transformer-type plasmatron, coupled with said high vacuum processing chamber; and
at least one gas source, coupled with said transformer-type plasmatron, for introducing at least one gas into said transformer-type plasmatron,
said high vacuum processing chamber comprising at least one entry-port,
said transformer-type plasmatron comprising:
a radio frequency power source, for generating alternating current power;
a plurality of conductors, coupled with said radio frequency power source;
a closed loop discharge chamber, for confining said at least one gas;
a plurality of high permeability magnetic cores, coupled around an outer portion of said closed loop discharge chamber and with said plurality of conductors;
a plurality of apertures, located along an inner portion of said closed loop discharge chamber; and
at least two dielectric gaskets, for coupling said inner portion with said outer portion,
said at least one entry-port configured to receive said inner portion such that said inner portion physically penetrates said high vacuum processing chamber,
said plurality of conductors forming a primary winding around said plurality of high permeability magnetic cores,
said at least one gas in said closed loop discharge chamber forming a secondary winding around said plurality of high permeability magnetic cores,
said transformer-type plasmatron igniting said at least one gas into at least one respective plasma when said plurality of conductors are provided with said alternating current power,
said plurality of apertures releasing said at least one respective plasma from said inner portion into said high vacuum processing chamber, and
said outer portion and said inner portion each referring to a position of said closed loop discharge chamber with respect to said high vacuum processing chamber.

2. The plasma generating apparatus according to claim 1, further comprising:
a pressure gauge;
a mass spectrometer; and
a reflective high energy electron diffraction tool.

3. The plasma generating apparatus according to claim 1, further comprising:
a target transport mechanism;
an infrared pyrometer;
a film thickness monitor;
a film deposition controller;
an ion source; and
an ellipsometer.

4. The plasma generating apparatus according to claim 1, said high vacuum processing chamber further comprising:
a high vacuum pump, for pumping air out of said high vacuum processing chamber;
a target, for being sprayed with said at least one respective plasma;
a target holder, for holding said target;
a target heater, for heating said target;
a shutter, for covering said target;
a target manipulator, for manipulating said target;
at least one Knudsen cell evaporation source, for providing vapors from at least one element into said high vacuum processing chamber; and
an electron gun evaporator, for providing metal vapors into said high vacuum processing chamber.

5. The plasma generating apparatus according to claim 4, wherein said high vacuum pump, said shutter, said target manipulator, said at least one Knudsen cell evaporation source and said electron gun evaporator are coupled with the outside of said high vacuum processing chamber.

6. The plasma generating apparatus according to claim 4, wherein said target, said target holder and said target heater are coupled with the inside of said high vacuum processing chamber.

7. The plasma generating apparatus according to claim 1, said transformer-type plasmatron further comprising:
at least one connection flange, coupled with said outer portion; and
a capacitance pressure gauge, coupled with said outer portion,
wherein a respective one of said at least one connection flange is coupled with a respective one of said at least one entry-port via a respective one of said at least two dielectric gaskets.

8. The plasma generating apparatus according to claim 1, wherein the pressure in said high vacuum processing chamber is substantially between 10⁻⁴ to 10⁻¹⁰ Pascals.

9. The plasma generating apparatus according to claim 1, said transformer-type plasmatron further comprising an impedance matching network coupled with radio frequency power source.

10. The plasma generating apparatus according to claim 1, wherein said outer portion is for generating said at least one respective plasma and wherein said inner portion is for releasing said at least one respective plasma into said high vacuum processing chamber.

11. The plasma generating apparatus according to claim 4, wherein said inner portion is configured to surround said target.

12. The plasma generating apparatus according to claim 4, wherein said inner portion is positioned in said high vacuum processing chamber slightly below said target.

13. The plasma generating apparatus according to claim 4, wherein said plurality of apertures are positioned at a distance to said target which is less than a mean free path distance of said at least one respective plasma.

14. The plasma generating apparatus according to claim 4, wherein said plurality of apertures are positioned along said inner portion symmetrically around said target.

15. The plasma generating apparatus according to claim 1, further comprising a plurality of sleeves, each one of said plurality of sleeves being inserted into a respective one of said plurality of apertures, each one of said plurality of sleeves comprising a nozzle end facing said high vacuum processing chamber, wherein said nozzle end is directed radially towards a target.

16. The plasma generating apparatus according to claim 15, said nozzle end comprising a particular cross-sectional shape.

17. The plasma generating apparatus according to claim 15, wherein said plurality of sleeves is produced from a material selected from the list consisting of:
a refractory metal;
ceramics;
silica glass;
pyrolytic boron nitride;
and graphite.

18. The plasma generating apparatus according to claim 1, said transformer-type plasmatron further comprising:
a gas inlet leaking valve;
a view port; and
a magnetic ring current gauge.

19. The plasma generating apparatus according to claim 1, wherein said inner portion comprises at least one inlet pipe and at least one outlet pipe for circulating a coolant in said inner portion.

20. The plasma generating apparatus according to claim 1, wherein said outer portion comprises at least one inlet pipe and at least one outlet pipe for circulating a coolant in said outer portion.

21. Plasma generating apparatus comprising:
a vacuum processing chamber;
a transformer-type plasmatron, coupled with said vacuum processing chamber; and
at least one gas source, coupled with said transformer-type plasmatron, for introducing at least one gas into said transformer-type plasmatron,
said vacuum processing chamber comprising at least one entry-port,
said transformer-type plasmatron comprising:
a radio frequency power source, for generating alternating current power;
a plurality of conductors, coupled with said radio frequency power source;
a closed loop discharge chamber, for confining said at least one gas;
a plurality of high permeability magnetic cores, coupled around an outer portion of said closed loop discharge chamber and with said plurality of conductors;
at least one aperture, located along an inner portion of said closed loop discharge chamber; and
at least two dielectric gaskets, for coupling said inner portion with said outer portion, while electrically isolating said inner portion from said outer portion,
said at least one entry-port configured to receive said inner portion such that said inner portion physically penetrates said vacuum processing chamber,
said plurality of conductors forming a primary winding around said plurality of high permeability magnetic cores,
said at least one gas in said closed loop discharge chamber forming a secondary winding around said plurality of high permeability magnetic cores,
said transformer-type plasmatron igniting said at least one gas into at least one respective plasma when said plurality of conductors are provided with said alternating current power,
said at least one aperture releasing said at least one respective plasma from said inner portion into said vacuum processing chamber, and
said outer portion and said inner portion each referring to a position of said closed loop discharge chamber with respect to said vacuum processing chamber.

22. The plasma generating apparatus according to claim 1, further comprising a wire loop, coupled with said transformer-type plasmatron, for measuring the voltage in said closed loop discharge chamber.

23. The plasma generating apparatus according to claim 7, wherein said capacitance pressure gauge is for measuring the pressure inside said closed loop discharge chamber.

24. The plasma generating apparatus according to claim 1, wherein said at least one respective plasma is crude plasma.

25. The plasma generating apparatus according to claim 1, wherein said target is selected from the list consisting of:
a wafer;
a film;
a fiber; and
a roll.

26. The plasma generating apparatus according to claim 1, wherein a shape of said high vacuum processing chamber is selected from the list consisting of:
a cylinder;
a cube; and
a sphere.

27. The plasma generating apparatus according to claim 1, wherein said high vacuum processing chamber is constructed from stainless steel.

28. The plasma generating apparatus according to claim 1, wherein said high vacuum processing chamber is selected from the list consisting of:
a barrel-type processing chamber;
a batch wafer processing chamber; and
a roll-to-roll processing chamber.

29. The plasma generating apparatus according to claim 1, wherein a shape of said closed loop discharge chamber is selected from the list consisting of:
a rectangular shape;
a toroidal shape;
a split loop shape;
a symmetric shape;
a circular shape;
an interpenetrating loop shape;
an interpenetrating square shape;
a square shape;
an interpenetrating shaft shape; and
a linear shape.

30. The plasma generating apparatus according to claim 1, wherein said closed loop discharge chamber is operated at low vacuum conditions.

31. The plasma generating apparatus according to claim 30, wherein said low vacuum conditions comprise pressures substantially between 0.1 to 10 Pascals.

32. The plasma generating apparatus according to claim 1, wherein said closed loop discharge chamber comprises non-conductive walls.

33. The plasma generating apparatus according to claim 4, wherein a distance between adjacent ones of said plurality of apertures is substantially equal to the distance between said plurality of apertures and said target.

34. The plasma generating apparatus according to claim 4, wherein said at least one Knudsen cell evaporation source is angled to deposit said vapors on a majority of the surface of said target.

35. The plasma generating apparatus according to claim 4, wherein said plurality of apertures are positioned at a distance to said target which is greater than a mean free path distance of said at least one respective plasma.

36. The plasma generating apparatus according to claim 15, further comprising a respective plurality of flanges, for coupling said plurality of sleeves with an inner wall of said closed loop discharge chamber.

37. The plasma generating apparatus according to claim 16, wherein said particular cross-sectional shape is selected from the list consisting of;
a cylinder;
a cone;
an ellipse;
a parabola;
a hyperbola;
a straight shape having a circular profile;
an inclined shape having an elliptical profile;
a triangular shape having a triangular profile;
a conical shape having a conical profile;
a parabolic shape having a parabolic profile; and
a hyperbolic shape having a hyperbolic profile.

38. The plasma generating apparatus according to claim 16, wherein the larger dimension of said particular cross-sectional shape is directed towards a target.

39. The plasma generating apparatus according to claim 18, wherein said a view port is for conducting spectroscopic analysis of said at least one respective plasma.

40. The plasma generating apparatus according to claim 1, wherein said closed loop discharge chamber is split into a plurality of electrically isolated sections.

41. The plasma generating apparatus according to claim 40, wherein each one of said plurality of electrically isolated sections is constructed from double-walled water-cooled stainless steel tubing.

42. The plasma generating apparatus according to claim 41, wherein an inner diameter of said double-walled water-cooled stainless steel tubing is larger than a mean free path distance of said at least one respective plasma.

43. The plasma generating apparatus according to claim 41, wherein a coolant is introduced into the double walls of said double-walled water-cooled stainless steel tubing of at least one of said plurality of electrically isolated sections at a lowest point of said at least one of said plurality of electrically isolated sections and is exited from said double walls of said double-walled water-cooled stainless steel tubing of said at least one of said plurality of electrically isolated sections at a highest point of said at least one of said plurality of electrically isolated sections.

44. The plasma generating apparatus according to claim 40, wherein said at least two dielectric gaskets electrically separate said plurality of electrically isolated sections.

45. The plasma generating apparatus according to claim 40, wherein said at least two dielectric gaskets are sandwiched between at least two respective flanges.

46. The plasma generating apparatus according to claim 40, wherein one of said plurality of electrically isolated sections is grounded with said high vacuum processing chamber.

47. The plasma generating apparatus according to claim 1, wherein said at least two dielectric gaskets are constructed from Teflon®.

48. The plasma generating apparatus according to claim 1, wherein said high vacuum processing chamber is electrically isolated from said closed loop discharge chamber.

49. The plasma generating apparatus according to claim 1, wherein said inner portion of said closed loop discharge chamber is positioned at an angle to said outer portion of said closed loop discharge chamber.

50. The plasma generating apparatus according to claim 1, further comprising at least one respective Teflon® ring, for sealing said at least one entry-port.

51. The plasma generating apparatus, according to claim 1, wherein a size of said plurality of apertures is substantially small to maintain a large Knudsen number in said high vacuum processing chamber.

52. The plasma generating apparatus according to claim 19, wherein said at least one inlet pipe and said at least one outlet pipe are coupled with said inner portion using a plurality of dielectric feed-thrus.

53. The plasma generating apparatus according to claim 20, wherein said at least one inlet pipe and said at least one outlet pipe are coupled with said outer portion using a plurality of dielectric feed-thrus.

54. The plasma generating apparatus according to claim 1, wherein said closed loop discharge chamber comprises a split shape section, said split shape section comprising a plurality of symmetrical paths.

55. The plasma generating apparatus according to claim 54, wherein each one of said plurality of symmetrical paths is substantially identical in topology, diameter and length.

56. The plasma generating apparatus according to claim 1, wherein said closed loop discharge chamber comprises an interpenetrating shape, said interpenetrating shape comprising a larger diameter tube and a smaller diameter tube, said smaller diameter tube being inserted into said larger diameter tube.

57. The plasma generating apparatus according to claim 56, wherein a shape of said smaller diameter tube is selected from the list consisting of:
a circle;
a square; and
a hexagon.

58. The plasma generating apparatus according to claim 56, wherein a shape of said larger diameter tube is selected from the list consisting of:
a square;
a rectangle; and
a line.

59. The plasma generating apparatus according to claim 56, wherein a central axis of said smaller diameter tube is offset from a central axis of said larger diameter tube.

60. The plasma generating apparatus according to claim 56, wherein a diameter of said larger diameter tube is substantially double a diameter of said smaller diameter tube.

61. The plasma generating apparatus according to claim 56, wherein said smaller diameter tube is proximate to an inner wall of said larger diameter tube.

62. The plasma generating apparatus according to claim 56, wherein said smaller diameter tube is coupled with said larger diameter tube using a plurality of dielectric seals.

63. The plasma generating apparatus according to claim 56, wherein said smaller diameter tube is welded to said larger diameter tube.

64. The plasma generating apparatus according to claim 1, wherein said closed loop discharge chamber comprises an interpenetrating shaft shape.

65. The plasma generating apparatus according to claim 64, wherein a target is positioned parallel to a lengthwise axis of said interpenetrating shaft shape.

66. The plasma generating apparatus according to claim 64, wherein a target is positioned perpendicular to a lengthwise axis of said interpenetrating shaft shape.

67. The plasma generating apparatus according to claim 64, further comprising a coolant pipe, said coolant pipe having a substantially equivalent potential to the potential of said transformer-type plasmatron.

68. The plasma generating apparatus according to claim 64, further comprising a bellows, coupled with said at least one entry-port.

69. The plasma generating apparatus according to claim 64, further comprising a harmonic oscillator, coupled with said at least one entry-port.

70. The plasma generating apparatus according to claim 1, said inner portion of said closed loop discharge chamber comprising:
a plurality of lips, for holding at least one dielectric gasket;
a ring, surrounding said at least one dielectric gasket;
a plurality of caps;
a dielectric sleeve, surrounding said at least one dielectric gasket; and
a protecting layer, surrounding said dielectric sleeve.

71. The plasma generating apparatus according to claim 70, wherein said ring is constructed from a material selected from the list consisting of:
ceramics; and
pyrolytic boron nitride.

72. The plasma generating apparatus according to claim 70, wherein said dielectric sleeve and said protecting layer each have an annular form.

73. The plasma generating apparatus according to claim 70, wherein said dielectric sleeve is constructed from a material selected from the list consisting of:
silica fabric tape;
silica; and
ceramics.

74. The plasma generating apparatus according to claim 70, wherein said protecting layer is a metal foil constructed from a material selected from the list consisting of:
tantalum;
stainless steel; and
molybdenum.

75. The plasma generating apparatus according to claim 1, said outer portion of said closed loop discharge chamber comprising:
a plurality of lips, for holding at least one dielectric gasket;
a plurality of caps; and
a shield, for surrounding said at least one dielectric gasket.

76. The plasma generating apparatus according to claim 75, wherein said plurality of caps is constructed from stainless steel.

77. The plasma generating apparatus according to claim 75, wherein said shield is coupled with said outer portion by a weld joint.

78. The plasma generating apparatus according to claim 75, wherein said shield is constructed from a material selected from the list consisting of:
stainless steel;
tantalum; and
molybdenum.

79. The plasma generating apparatus according to claim 75, each one of said plurality of caps comprising a gripping tooth.

80. The plasma generating apparatus according to claim 1, said at least one entry-port comprising:
an inner tube, comprising a first protrusion;
a port flange, comprising a second protrusion and a first recess;
a first flange, comprising a second recess;
a second flange; and
a gasket ring.

81. The plasma generating apparatus according to claim 80, wherein said port flange, said first flange and said second flange each comprise a plurality of screw holes.

82. The plasma generating apparatus according to claim 81, further comprising:
a plurality of dielectric bushings, respectively inserted into said plurality of screw holes; and
a plurality of sleeves.

83. The plasma generating apparatus according to claim 80, wherein a shape of said gasket ring matches a shape of said first recess and said second recess.

84. The plasma generating apparatus according to claim 80, wherein said gasket ring has a polygonal cross-sectional shape.

85. The plasma generating apparatus according to claim 1, further comprising a plurality of rollers, for rolling a target in said high vacuum processing chamber.

86. The plasma generating apparatus according to claim 1, further comprising at least one other transformer-type plasmatron, coupled with said high vacuum processing chamber.

87. The plasma generating apparatus according to claim 86, said at least one other transformer-type plasmatron comprising at least one closed loop discharge chamber.

88. Plasma generating apparatus comprising:
a high vacuum processing chamber;
a transformer-type plasmatron, coupled with said high vacuum processing chamber; and
at least one gas source, coupled with said transformer-type plasmatron, for introducing at least one gas into said transformer-type plasmatron,
said high vacuum processing chamber comprising at least one entry-port,
said transformer-type plasmatron comprising:
a radio frequency power source, for generating alternating current power;
a plurality of conductors, coupled with said radio frequency power source;
a closed loop discharge chamber, for confining said at least one gas;
a plurality of high permeability magnetic cores, coupled around an outer portion of said closed loop discharge chamber and with said plurality of conductors;
a plurality of apertures, located along an inner portion of said closed loop discharge chamber; and
at least one dielectric gasket, for coupling said inner portion with said outer portion,
said at least one entry-port configured to receive said inner portion such that said inner portion physically penetrates said high vacuum processing chamber,
said plurality of conductors forming a primary winding around said plurality of high permeability magnetic cores,
said at least one gas in said closed loop discharge chamber forming a secondary winding around said plurality of high permeability magnetic cores,
said transformer-type plasmatron igniting said at least one gas into at least one respective plasma when said plurality of conductors are provided with said alternating current power,
said plurality of apertures releasing said at least one respective plasma from said inner portion into said high vacuum processing chamber, and
said outer portion and said inner portion each referring to a position of said closed loop discharge chamber with respect to said high vacuum processing chamber.
